(19) United States
(12) Patent Application Publication
(10) Pub. No.: US 2007/0212510 A1
(43) Pub. Date: Sep. 13, 2007

(54) Thin silicon or germanium sheets and photovoltaics formed from thin sheets

(76) Inventors: Henry Hieslmair, Mountain View, CA (US); Ronald J. Mosso, Fremont, CA (US); Robert B. Lynch, Livermore, CA (US); Shivkumar Chiruvolu, San Jose, CA (US); William E. McGovern, Lafayette, CA (US); Craig R. Horne, Sunnyvale, CA (US); Narayan Solayappan, Cupertino, CA (US); Ronald M. Cornell, Livermore, CA (US)

Correspondence Address: DARDI & ASSOCIATES, PLLC, 220 S. 6TH ST., SUITE 2000, U.S. BANK PLAZA, MINNEAPOLIS, MN, 55402, US

(21) Appl. No.: 11/717,605

(22) Filed: Mar. 13, 2007

Related U.S. Application Data
(60) Provisional application No. 60/782,115, filed on Mar. 13, 2006.

(51) Int. Cl. B32B 33/00

(52) U.S. Cl. 428/40.1; 428/195.1

(57) ABSTRACT

Thin semiconductor foils can be formed using light reactive deposition. These foils can have an average thickness of less than 100 microns. In some embodiments, the semiconductor foils can have a large surface area, such as greater than about 900 square centimeters. The foil can be free standing or releasably held on one surface. The semiconductor foil can comprise elemental silicon, elemental germanium, silicon carbide, doped forms thereof, alloys thereof or mixtures thereof. The foils can be formed using a release layer that can release the foil after its deposition. The foils can be patterned, cut and processed in other ways for the formation of devices. Suitable devices that can be formed form the foils include, for example, photovoltaic modules and display control circuits.

### CROSS REFERENCE TO RELATED APPLICATIONS

The application claims priority to copending U.S. Provisional Patent Application Ser. No. 60/782,115, filed on Mar. 13, 2006 to Hieslmair et al., entitled “Thin Silicon or Germanium Sheets and Photovoltaics Formed From Thin Sheets,” incorporated herein by reference.

### FIELD OF THE INVENTION

The invention relates to thin sheets, which may be free standing, of elemental silicon, elemental germanium, alloys thereof, silicon carbide or doped materials thereof having a large surface area. The invention further relates to methods for forming free standing sheets with large surface areas. The invention also relates to structures incorporating thin sheets of elemental silicon, elemental germanium, alloys thereof, silicon carbide or doped materials thereof and in particular photovoltaic cells and display controllers.

### BACKGROUND OF THE INVENTION

Crystalline silicon is extensively used in the production of integrated circuits. For these applications, high purity silicon is used. Germanium has been suggested as an alternative to silicon as an inorganic semiconductor for integrated circuits. With respect to commercial silicon for semiconductor applications, large cylindrical ingots of silicon generally are grown, which are sliced to form wafers. Individual wafers are used for integrated circuit production using photolithography and the like along with suitable depositions approaches, such as chemical vapor deposition and physical vapor depositions.

With increasing costs and undesirable environmental effects from the use of fossil fuels and other non-renewable energy sources, there are growing demands for alternative forms of energy. Various technologies are available for the formation of photovoltaic cells, i.e., solar cells. A majority of commercial photovoltaic cells are based on silicon. Increased commercialization of alternative energy sources relies on increasing cost effectiveness through lower costs per energy unit, which can be achieved through improved efficiency of the energy source and/or through cost reduction for materials and processing. Thus, for a photovoltaic cell, the objective would be to increase energy conversion efficiency for a given light fluence and/or to lower the cost of producing a cell.

### SUMMARY OF THE INVENTION

In a first aspect, the invention pertains to a sheet of crystalline silicon, germanium, silicon carbide, doped materials thereof or alloys thereof having a surface area of at least about 900 square centimeters and an average thickness of no more than about 100 microns. The sheet generally is free-standing, although in some embodiments the sheet may be reversibly attached to a substrate. The crystalline silicon can be polycrystalline. While the sheet is generally free standing, if desired the sheet can be attached to a substrate, for example, with an adhesive or a release layer. The sheet can be cut into a plurality of elements with very similar properties, which can be assembled into a photovoltaic panel.

In a further aspect, the invention pertains to a method of forming a separable layer of silicon, germanium, silicon carbide, doped materials thereof or alloys thereof. The method comprises depositing a material from a reactive flow over a release layer on a substrate. The release layer, i.e., an underlayer, can comprise a material that is soluble in a solvent that can dissolve the release layer while not dissolving the separable layer of inorganic material. The release layer can be deposited from a reactive flow and can comprise a material with a softening temperature greater than the melting temperature of crystalline silicon. In some embodiments, the reaction within the reactive flow is driven by a light beam. The layer, such as a silicon layer, may be amorphous, crystalline or a combination thereof. Also, the as deposited layer may have a low density relative to bulk silicon up to a density approximating bulk material. In some embodiments, the methods can be used to form large area sheets of a wide range of selected inorganic materials. In additional embodiments, the release layer can be formed with a low density corresponding with a porosity of at least about 40 percent.

In another aspects, the invention pertains to a layer of an inorganic composition with a plurality of patterned islands of material, such as elemental silicon, elemental germanium, silicon carbide, doped materials thereof, or alloys thereof, on a surface of the inorganic composition in which the islands have an average thickness of no more than about 100 microns. The inorganic composition can comprise, for example, a metal oxide, a metal carbide, silicon nitride, silicon oxide, silicon oxynitride, silicon carbide and combinations thereof. In general, the layer of inorganic composition has an average thickness from about 20 nm to about 50 microns, while in some embodiments the layer of inorganic composition an average thickness of about 20 nm to about 200 nm and in other embodiments the layer of inorganic composition has a thickness of at least about 20 microns. The layer of inorganic composition can be associated with a release layer, or the islands, such as elemental silicon islands, may be associated with a release layer. A removable material may be located between the islands. In some embodiments, the layer of inorganic composition has an area of at least about 400 square centimeters. Similarly, the invention can pertain to a photovoltaic material comprising the layer of an inorganic composition with a plurality of patterned islands of crystalline silicon.

In other aspects, the invention pertains to a method for depositing elemental silicon, elemental germanium, silicon carbide, doped materials thereof or alloys thereof. The method can comprise depositing the material in a pattern on a substrate surface. The as deposited material, such as elemental silicon, can be crystalline or amorphous. The depositing step can comprise directing a reactive flow at the substrate surface, and in some embodiments the reactive flow can comprise the product of a reaction driven by a light beam. The patterning can be performed, for example, with a mask and/or with the controlled deposition of the silicon into the selected pattern. Suitable patterning includes, for example, the formation of stripes or islands. In some embodiments, the deposited material is textured, which may or may not correspond to texture on the substrate surface.

Furthermore, the invention pertains to a method for forming a photovoltaic panel. The method comprises assembling a plurality of sections onto a substrate surface in which each section comprises a crystalline silicon layer with an average thickness of no more than about 100 microns. The sections are assembled on the panel such that a plurality of the silicon layers is from a single sheet of crystalline silicon material cut to size. In some embodiments, the sheet can be cut while the sheet is adhered to a substrate surface with either a release layer or an adhering layer.

In further aspects, the invention relates to method for coating a textured substrate comprising reacting a flowing reactant stream to form a product stream and depositing at least a portion of the product composition onto a textured substrate. The textured substrate can comprise a rough surface with a peak to peak distance from about 50 nm to about 100 microns. The reaction of the flowing reactant stream can be driven with a light beam.

In additional aspects, the invention relates to a display comprising a control element and a plurality of light emitting elements with light emission of each element being under the control of the control element. The control element can comprise a sheet of silicon/germanium-based semiconductor having an average thickness of no more than about 100 microns. The sheet is patterned with transistors operably interfacing with the sheet.

### BRIEF DESCRIPTION OF THE DRAWINGS

FIG. 1 is a side perspective view of a reaction chamber for performing light reactive deposition at high production rates.

FIG. 2 is a schematic representation of a reactant delivery system for the delivery of vapor/gas reactants to a flowing reaction system, such as the reactor of FIG. 1.

FIG. 3 is a sectional side view of a reactant inlet nozzle with an aerosol generator for the delivery of aerosol and gas/vapor compositions into a reaction chamber, wherein the cross section is taken along line 3-3 of the insert. The insert shows a top view of an elongated reactant inlet.

FIG. 4 is a sectional side view of the reactant inlet nozzle of FIG. 3 taken along the line 44 of the insert in FIG. 3.

FIG. 5 is a schematic diagram of a light reactive dense deposition apparatus in which a dense coating is applied to a substrate within a reaction chamber.

FIG. 6 is a perspective view of a reactant nozzle delivering reactants to a reaction zone positioned near a substrate.

FIG. 7 is a sectional view of the apparatus of FIG. 6 taken along line 7-7.

FIG. 8 is a perspective view of an embodiment of a reaction chamber for performing light reactive dense deposition.

FIG. 9 is an expanded view of the reaction chamber of the light reactive deposition chamber of FIG. 8.

FIG. 10 is an expanded view of the substrate support of the reaction chamber of FIG. 8.

FIG. 11 is a perspective view of an alternative embodiment of an apparatus for performing light reactive dense deposition.

FIG. 12 is schematic diagram of the reactant delivery system of the apparatus in FIG. 11.

FIG. 13 is an expanded view of the reaction chamber of the apparatus of FIG. 11.

FIG. 14 is sectional view of the reaction chamber of FIG. 13 taken along line 14-14.

FIG. 15 is an alternative sectional view of the reaction chamber of FIG. 13 with the substrate holder portions removed and the baffle system visible.

FIG. 16 is a top view of the reactant inlet nozzle for the reaction chamber of FIG. 13.

FIG. 17 is a perspective view of a dual linear manipulator, which is part of the drive system for the nozzle of the reaction chamber of FIG. 13, where the dual linear manipulator is separated from the reaction chamber for separate viewing.

FIG. 18 is a schematic view of a light reactive deposition apparatus configured for transport of a large substrate.

FIG. 19 is a top view of a substrate with a powder coating covered in part with a mask.

FIG. 20 is a schematic perspective view of a layered structure with a release layer in which the arrow schematically depicts the separation of an overcoat layer from the layered structure.

FIG. 21 is schematic perspective view of a structured overcoat following removal from a release layer.

FIG. 22 is a fragmentary side view of layers of a layered overcoat structure.

FIG. 23 is a fragmentary side view of layers of an alternative embodiment of a layered overcoat structure.

FIG. 24 is a schematic perspective view of a large area layer with deposited islands patterned on the large area layer.

FIG. 25 is a top view of a transparent substrate with a plurality of semiconductor segments mounted on the transparent substrate for processing into photovoltaic cells.

FIG. 26 is a sectional side view of the structure in FIG. 25 taken along line 26-26 of FIG. 25.

FIG. 27 is a cut away side perspective view showing the interior of a light reactive deposition reaction chamber with a stage positioned to receive a produce flow from above.

FIG. 28 is a perspective view of the stage of FIG. 27 shown separated from the reaction chamber.

FIG. 29 is a photomicrograph of the top surface of the silicon foil as synthesized on a substrate by light reactive deposition.

FIG. 30 is a photomicrograph showing the edge where a fragment of silicon foil separated from the release layer and the remaining portion of the silicon foil is still attached.

FIG. 31 is a photograph showing a fragment of the silicon foil.

FIG. 32 is a photograph showing the opposite side of the silicon foil in FIG. 31 with the lighter color corresponding to remnants of the release layer.

### DETAILED DESCRIPTION OF THE INVENTION

Light reactive deposition approaches can be adapted advantageously for the production of large area and very thin sheets or foils, which can comprise, for example, elemental silicon, elemental germanium, silicon carbide, doped materials thereof or alloys thereof. These large area sheets, which generally can be free standing or releaseably bound to a substrate, can be advantageously used in a variety of applications. In particular, large area sheets of elemental silicon, elemental germanium, silicon carbide, doped materials thereof or alloys thereof can be advantageously used in the production of photovoltaic panels, integrated circuits, displays and the like.

Light reactive deposition involves a chemical reaction within a flow having suitable precursor reactants in which the reaction is driven by an intense light beam. The light reactive deposition approach can involve the deposition of the inorganic material onto a release layer so that the separable structure can be formed, although additional layers can be involved. The sheets can be produced with very high purity levels or with selected dopants or other additives while avoiding significant amounts of contaminants. In some embodiments, the layer of elemental silicon, elemental germanium, silicon carbide, doped materials thereof or alloys thereof can be deposited on another selected inorganic layer with or without patterning. The large area, thin sheets can be cut into a plurality of smaller sheets with high property uniformity within a particular sheet and between different sheets formed under equivalent conditions. In some embodiments, a release layer can be used to form a releasable inorganic layer with a patterned top surface.

While the use of a release layer makes it feasible to form a free standing structure, the inorganic sheet can be relatively fragile, so that it can be desirable to generally support the sheet releasably on a substrate. Thus, the sheet can be releasably held to enable transfer of the structure from one substrate to another as desired. For example, an adhesive holding the sheet onto a substrate generally can be released using a reasonable amount of force or a solvent.

Elemental silicon, elemental germanium and silicon carbide are electrical semiconductors at room temperature in pure form. Heating or suitable doping of elemental silicon, elemental germanium or silicon carbide results in a change in the electrical resistance. To simplify the notation herein, “silicon/germanium-based semiconductors” is used to represent elemental silicon, elemental germanium, silicon carbide, doped materials thereof or alloys thereof. In some embodiments, it is desirable to have sheets that are crystalline, such as polycrystalline. The crystallite size can influence the semiconductor properties, and a larger average crystallite size can be desirable to increase carrier mobilities and to increase minority carrier diffusion lengths. In appropriate embodiments, large sheets of silicon/germanium-based semiconductors can be processed into appropriate devices while saving material relative to thicker structures.

The ready controllability of the electrical conduction properties of elemental silicon has resulted in wide commercial use of silicon. For example, silicon is widely used to form semiconductors for integrated circuits. Silicon/germanium-based semiconductors formed through doping with elements with excess electrons, such as As, Sb and P, for populating the conduction bands are referred to as n-type semiconductors, and silicon/germanium-based semiconductors formed through doping with elements with electron deficiencies, such as B, Al, Ga, and In, for populating valance bands with conducting holes are referred to as p-type semiconductors.

A process has been developed involving reactive deposition driven by a light beam (e.g., a laser beam). In general, the coating can be used to form particular structures with either a simple or complex configuration. In one embodiment, reactive deposition driven by a light beam involves a reactor with a flowing reactant stream that intersects an electromagnetic radiation beam proximate a reaction zone to form a product stream configured for the deposition of product material onto a surface placed to intersect the product flow. This process has been given the name Light Reactive Deposition (LRD™). In some embodiments, the particles are deposited in the form of a powder coating, i.e. a collection of unfused particles or a network of fused or partly fused particles in which at least some characteristics of the initial primary particles are reflected within the coating. This version of the process can be called light reactive powder coating deposition. Subsequently, it was discovered that the process could be modified for the formation of dense or moderately dense coatings. This version of the process can be referred to as light reactive dense deposition.

Laser pyrolysis is a light driven reactive flow process for powder production, i.e., for synthesis of submicron particles. Light reactive flow processes, such as laser pyrolysis and light reactive deposition, share common features of a constrained flowing reactive stream that intersects a light beam at a light reaction zone to form a product stream downstream from a light reaction zone. In light reactive flow processes, a reactant stream is pyrolyzed by an intense light beam, such as a laser beam, which heats the reactants at a very rapid rate. While a laser beam is a convenient energy source, other intense light sources can be used in light reactive deposition. Thus, the reaction conditions and deposition parameters can be selected to change the nature of the coating with respect to density and related properties, such as porosity and the like.

Light reactive deposition can be used in the production of a large range of product materials. Reactant delivery approaches provide for a wide range of reaction precursors in gaseous/vapor and/or aerosol form, and the composition of the product material generally is a function of the reactants as well as the reaction conditions. Light reactive deposition can be used to form highly uniform coatings of materials, optionally comprising dopant(s)/additive(s) and/or complex composition(s). Thus, the composition and material properties of the corresponding coating can be adjusted based on the features of the light reactive deposition approach.

In some embodiments, the light reactive deposition apparatus includes an elongated reactant inlet such that a stream of reactant precursors is generated as a flowing sheet that flows through an elongated reaction zone to form a product stream also in the form of a sheet. Generally, the reactant flow is oriented to intersect the radiation such that most or all of the reactant flow intersects with the radiation such that high yields are obtained. Using the elongated reactant inlet, a line or stripe of coating material at a high throughput can be, at least in part, simultaneously deposited onto a substrate. By moving the substrate through the product stream, a large area coating can be applied with one or more sweeps. A high reactant throughput with a corresponding high material production rate can be maintained without sacrificing control of uniformity of the deposited coating. By depositing a line or stripe of particles from the flowing product sheet, the coating process can be performed more rapidly.

In some embodiments, light reactive deposition can be used to form coatings with high thickness uniformity and smooth coating surfaces. Appropriate controls of the deposition process can result in high uniformity of coating thickness, whether or not densified, across the surface of a substrate and with respect to average coating thickness between substrates coated under the equivalent conditions. Light reactive deposition is described generally in copending U.S. patent application Ser. Nos. 09/715,935 to Bi et al., entitled “Coating Formation By Reactive Deposition,” and 10/414,443 to Bi et al., entitled “Coating Formation By Reactive Deposition,” both of which are incorporated herein by reference. As described below, texture can be introduced without losing the advantages relating to uniformity and smoothness since these qualities are superimposed on a coarser texture.

Inorganic coatings with various stoichiometries and/or non-stoichiometric compositions can be produced by light reactive deposition. Similarly, deposited materials can be formed with various crystal structure(s). Specifically, light reactive deposition can be used to form highly uniform coatings of glasses, i.e., amorphous materials, and crystalline materials (either single crystalline or polycrystalline), optionally with additive/dopants and/or complex stoichiometries. As described herein, there is specific interest in crystalline elemental silicon/germanium, optionally with a dopant.

A basic feature of successful application of light reactive deposition for the production of coatings with desired compositions is generation of a reactant stream containing an appropriate precursor composition. In particular, for the formation of doped materials by light reactive deposition, the reactant stream can comprise host precursors and dopant precursors. The reactant stream comprises appropriate relative amounts of precursor compositions to produce the materials with the desired compositions and/or dopant concentrations. Also, unless the precursors are an appropriate radiation absorber, an additional radiation absorber can be added to the reactant stream to absorb radiation/light energy for transfer to other compounds in the reactant stream. Other additional reactants can be used to adjust the oxidizing/reducing environment in the reactant stream. In general, the substrate can be porous or non-porous, flexible or rigid, planar or curved, textured or smooth or appropriate combinations thereof.

Multiple layers of coating material can be formed by additional sweeps of the substrate through the product particle stream. Since each coating layer can have high uniformity and smoothness, a large number of layers can be stacked while maintaining appropriate control on the layered structure such that structural features can be formed throughout the layered structure without structural variation adversely affecting performance of the resulting structures. Composition can be varied between layers, i.e., perpendicular to the plane of the structure, and/or portions of layers, within the plane of the structure, to form desired structures. The composition of the product coating material may or may not be varied within a single pass and/or between passes. Similarly, density can be varied to impose different porosities or other properties to the material.

Layers generally can be applied sequentially, although near-simultaneous or even simultaneous application at displaced locations can also be used. If several passes are made to deposit the same composition of coating material, the individually deposited layers may or may not be considered separate layers in the completed structure depending on whether or not the separately deposited layers can be subsequently identified as distinguishable features. By depositing layers with uniform structures and desired composition variation, complex structures spanning many layers can be formed. The use of light reactive deposition for the formation of three dimensional structures, especially for optical applications, is described further in U.S. Pat. No. 6,952,504 to Bi et al., entitled “Three Dimensional Engineering of Planar Optical Structures,” incorporated herein by reference.

In some embodiments, the formation of the three dimensional structures generally is based on the deposition of a plurality of layers, each of which may or may not be contoured or patterned to form a particular structure within a specific layer. For example, different functional structures can be formed by varying deposited material in the z-plane, i.e., the plane perpendicular to the coated substrate plane. Also, approaches have been developed for the patterning of compositions for the formation of desired structures. In general, the composition along the x-y plane at a particular level or layer within the three dimensional structure can be varied during the deposition process or following deposition by patterning the materials, either before, during or after any further densification process, such as a heat treatment or the like. Patterning of materials with respect to composition or other property can be performed following deposition, for example, using patterning approaches, such as lithography and/or photolithography, along with etching, such as chemical etching and/or radiation-based ablation, form desired patterns in one or more layers. Thus, using light reactive deposition possibly with other patterning approaches, it is possible to form complex structures with intricate variation of materials with selectively varying compositions.

With respect to patterning during the deposition process, the composition of product material deposited on the substrate can be changed during the deposition process to deposit coating material with a particular composition at selected locations on the substrate to vary the resulting composition of the material along the x-y plane. Using light reactive deposition, the product composition can be varied by adjusting the reactants that react to form the product material or by varying the reaction conditions. For example, the reaction chamber pressure, flow rates, radiation intensity, radiation energy/wavelength, concentration of inert diluent gas in the reaction stream, temperature of the reactant flow, position of the substrate to interface with the product flow can affect the composition, density and other properties of the product coating.

In other embodiments, a discrete mask is used to control the deposition of coating material. A discrete mask can provide an efficient and precise approach for the patterning of coating material. With light reactive deposition, the coating material has a specific momentum such that a mask with a flat surface placed against another flat surface can provide sufficient contact to prevent significant material migration past the boundary of the mask. The discrete mask has openings at selected locations. Also, the discrete masks can have an intact self-supporting structure that is not bonded to the surface such that the mask can be removed intact from the surface that is coated.

In some embodiments, it is desirable to perform a heat treatment of the as-formed coating. For less dense coatings, the heat treatment can consolidate or sinter the materials to densify the coatings to more closely approximate the bulk material density. Additionally or alternatively, whether or not densifying the coating, the heat treatment can anneal the coating material to induce greater uniformity with respect to overall properties, such as crystallinity.

For convenience, the term consolidate is used herein to described densification of an amorphous or crystalline material. To consolidate the materials, the powders are heated to a temperature above their flow temperature. At these temperatures, the powders densify and upon cooling form a layer of densified material. The densification may or may not yield a material that approximates the bulk density of the composition. By controlling the composition and/or dopants of the deposited particles, the composition of a subsequently densified material can be controlled to be a desired composition. Generally, amorphous particles can be consolidated to form a glass material, and crystalline particles can be consolidated to form a crystalline material. However, in some embodiments, appropriate heating and quenching rates can be used to consolidate an amorphous material into a crystalline layer, either single crystalline or polycrystalline, (generally slow quenching rates) and a crystalline powder into a glass layer (generally a rapid quench).

The densification generally is performed with controlled heating of the composition. The flow temperatures generally depend on the composition and to some extent on the primary particle size, especially for a less dense powder coating, since smaller particles in the submicron range generally exhibit flow at lower temperatures than corresponding larger particles with the same composition. The layers can be consolidated after formation of a particular layer or portion thereof, or a plurality of layers can be consolidated at the same time. By selecting materials with appropriate flow temperatures, the structure can be heated to consolidate one or more layers to form densified materials while other layers can remain as an unconsolidated coating, such as a powder coating.

With respect to consolidation of crystalline silicon/germanium-based semiconductors, an approach termed zone-melt recrystallization (ZMR) can be used to process the silicon to obtain a desired degree of crystallinity and/or to fully densify the material. In ZMR, the structure is heated through one surface to a high temperature but below the melting point for silicon. Then, a strip heater or the like is scanned across the same and/or opposite surface to form a stripe of melted silicon that recrystallizes along a front as the strip heater movesalong the surface. ZMR is described further, for example, in U.S. Pat. No. 5,540,183 to Deguchi et al., entitled “Zone-Melt Recrystallization of Semiconductor Materials,” and in an article by Yokoyama et al., Journal of the Electrochemical Society, 150 (5), A594-A600 (2003), entitled “Fabrication of SOI Films with High Crystal Uniformity by High-Speed-Zone Melt Crystallization,” both of which are incorporated herein by reference.

A laser spot can also be rastered across the surface to produce a molten spot which recrystallizes. It may also be possible to heat the entire sample to the melting point of silicon with subsequent cooling to re-crystallize the silicon.

In light reactive dense deposition, the coating conditions can be selected to directly form a desired dense coating possibly without applying any further processing to densify/consolidate the coating, although additional processing can still be performed to obtain desired coating properties. In some embodiments, a coating material can be deposited at a density of at least about 55 percent and in further embodiments from about 65 percent density up to the full density of the fully densified material. An as deposited dense coating may not have features reflecting an underlying primary particle size, such as particulate features or large pores, corresponding to properties of particles that collect on the surface to form a powder coating. In some embodiments, the resulting dense coating is a non-porous material with respect to gas absorption/adsorption. In contrast, with light reactive powder coating deposition, particles are formed within a reactive flow that are deposited as a soot or snow, e.g., a powder coating, with a relatively low density relative to the fully densified material, onto the substrate surface. Light reactive dense deposition is described further in copending U.S. patent application Ser. No. 11/017,214 to Chinuvolu et al., entitled “Dense Coating Formation By Reactive Deposition,” incorporated herein by reference.

The reaction parameters can be adjusted to deposit the denser material coating, for example, through the appropriate selection of the reactant/product flow parameters, the position of the substrate relative to the light reaction zone, the relative concentration of inert diluent gas and other reaction parameters. In light reactive dense deposition, reaction conditions and deposition parameters can be selected to deposit coalescing species onto the substrate. The substrate surface can provide the necessary conditions for heterogeneous nucleation and film growth. In particular, the substrate surface can be heated to a relatively high temperature to enhance uniform film growth. In some embodiments, the substrate can be heated during or prior to the deposition to reduce thermal stress of to stimulate compaction of the particles during the deposition prior to a subsequent melting process to facilitate coalescing of the particles into a dense layer. In other embodiments, the heating of the substrate to relatively high temperatures can be used to facilitate direct deposition of crystalline silicon/germanium-based semiconductors as a relatively dense thin layer.

For the formation of the structures described herein, the light reactive deposition process can comprise the deposition of a release layer. A release layer can enable the separation of an overcoat structure from the substrate, in which the overcoat structure is formed with one or more additional coating steps and optionally with further processing while the structure is associated with the release layer. In particular, a release layer has properties that provide for the release layer to decouple from an underlying substrate, an overcoat or both. With the ability to separate an overcoat structure from the underlying substrate, the large area and thin elemental silicon and/or germanium foils can be formed as well as other structures. The separated structures can be processed into desired devices, such as photovoltaic devices or displays.

The release layer can have distinct properties that distinguish it from a layer above and the substrate below. The term substrate is used in the broad sense of the material surface contacting the release layer on which the release layer was deposited, whether or not the substrate surface layer was itself deposited as a coating on a further underlying substrate. The release layer may differ from the layer above and the substrate below with respect to composition and/or properties, such as density, such that it is susceptible to fracture. In alternative or additional embodiments, the release layer can comprise a composition that is soluble in a selected solvent.

With respect to the release layer as a fracture layer, the release layer generally has a substantially lower density than either the underlying substrate or the overcoat. The lower density of the fracture layer can be a result of the deposition process and/or due to processing following deposition. For example, preferentially densifying the over-layer while leaving the release layer at a lower density is described in U.S. Pat. No. 6,788,866 to Bryan, entitled “Layer Materials and Planar Optical Devices,” incorporated herein by reference. As a result of the lower density, the release layer generally can be fractured without damaging the substrate or overcoat.

With respect to the deposition process, the processing parameters can be adjusted to deposit the release layer at a significantly lower density than the overcoat layer. The differences in density can be adjusted to yield the desired differences in mechanical strength such that the release layer can be fractured to form the overcoat as a free standing structure or a releasably supported structure. For example, the release layer can be deposited as a coating with a density corresponding with a release layer porosity of at least about 40 percent.

The resulting structure may have a portion of the fractured release layer attached. Residual portions of the release layer associated with the released overcoat structure can be removed with various methods including, for example, chemical etching, plasma etching and/or mechanical polishing. Similarly, substrates can be similarly cleaned to remove residual release layer material using chemical cleaning and/or mechanical polishing. Thus, a high quality substrate structure can be reused multiple times while taking advantage of the high quality of the substrate.

In alternative or additional embodiments, the composition of the release layer and the overcoat layer are different such that the compositional differences can be exploited to facilitate the function of the release layer. In some embodiments, the different compositions can be selected such that the release layer and the overcoat layer have different consolidation temperatures. Specifically, the release layer can have a higher consolidation temperature so that the overcoat can be densified while the release layer remains substantially unconsolidated with a lower density. The different compositions may involve different dopant levels, dopant composition and/or different host materials. The consolidation of the overcoat layer and the substantial non-consolidation of the release layer can result in a substantial density difference between the release layer and the overcoat material that can be exploited to fracture the release layer. The use of differential consolidation temperatures for processing adjacent layers into different density materials and fracturing of the release layer is described further in U.S. Pat. No. 6,788,866 to Bryan, entitled “Layer Materials and Planar Optical Devices,” incorporated herein by reference.

However, in some embodiments, the release layer functions through the specific properties of the composition rather than density. Specifically, the composition of the release layer is distinct from the composition of the overcoat layer such that further processing can remove or damage the release layer. For example, the release layer can be formed from a soluble material that can be dissolved to release the overcoat material. A range of inorganic compositions are suitable for a release composition. For example, a metal chloride or metal nitrate can be deposited using an aerosol without any further reactants so that a coating of unreacted metal compound are deposited in the process, although in other embodiments the release layer composition can be a reaction product within the coating stream. The soluble inorganic composition can be deposited with any reasonable density. The deposition of a soluble inorganic composition using light reactive powder coating deposition for the formation of elements of an electrochemical cell is described in copending U.S. patent application Ser. No. 10/854,931 to Home et al., entitled “Reactive Deposition for Electrochemical Cell Production,” incorporated herein by reference.

Thus, a release layer can provide a mechanism to release the overcoat material with a desired composition and structure. In some embodiments, the overcoat material can comprise silicon/germanium-based semiconductor structures. The material may or may not comprise a selected amount and composition of a dopant. Appropriate processing steps can be performed before or after release from the substrate depending on the desired objectives and processing convenience for forming the ultimate device.

In some embodiments of large area, thin layers of silicon/germanium-based semiconductors, the free standing structures can have an area of at least about 900 square centimeters. Similarly, the sheets can have an average thickness of no more than about 100 microns. The large area and small thickness can be exploited in unique ways in the formation of improved devices while saving on material cost and consumption. Furthermore, in some embodiments, the thin silicon/germanium semiconductor layers can have a thickness of at least about 2 microns.

In additional or alternative embodiments, one or more thin elemental silicon/germanium structures can be associated with another layer which can facilitate the formation of the ultimate desired structure. Suitable associated layers can be compositions comprising a silicon composition, a germanium composition and/or other inorganic compositions. For example, a layer can be an electrically insulating layer on one or both surfaces of the semiconductor. The associated layers can be formed either above or below the layer(s) of silicon/germanium-based semiconductor relative to the release layer. The thickness and composition of the associated layer(s) generally are selected based on the desired use of the structure.

For the formation of devices based on a semiconductor sheet, the structure generally is manipulated to have appropriate localized features that form elements of the devices. Specifically, it may be desirable to pattern the silicon/germanium-based semiconductor structures. This patterning can facilitate subsequent device formation. The features can be patterned by the modification of the silicon/germanium-based semiconductor sheet and/or by the deposition of materials onto the structure. Modification of the sheet can relate to compositional changes and/or to physical changes. For example, in some embodiments, the sheet can be doped at particular locations along the sheet. With respect to deposition of materials onto the sheet, appropriate materials can be deposited onto selected locations along the semiconductor sheet to form elements of devices. Any structural additions onto the sheet can be performed using light reactive deposition or any other appropriate deposition approach. In particular, printing processes, such as inkjet printing can be used to deposit at specific locations dopant compositions to provide dopant to modify the silicon/germanium-based semiconductor sheet and/or to provide a composition, such as a polysilane, that can be processed into a semiconductor layer.

With respect to reactive deposition, it may be desirable to form stripes, islands or the like of the silicon/germanium-based semiconductor on an under-layer. If the under-layer is formed adjacent a release layer, the patterned silicon/germanium-based semiconductor structures can be formed over an under-layer with or without another material between the under-layer and the silicon/germanium-based semiconductor structures. Alternatively, a silicon/germanium layer(s) on an under-layer can be patterned through etching or the like following the deposition of the silicon/germanium-based semiconductor layer(s). This etching can be performed before, after or during a heat treatment step. If the silicon/germanium-based semiconductor layer(s) is adjacent a release layer and an associated layer is placed over the silicon/germanium-based semiconductor layer(s), the patterning can be performed during deposition through the use of a dissolvable material or following removal from the release layer through the use of etching or the like.

In some embodiments, structures can comprise both an under-layer and an associated layer on the respective sides of the silicon/germanium-based semiconductor layer(s). Also, an under-layer and/or an associated layer may or may not provide a functional role in a resulting device. Thus, the ability to form an under-layer or an associated layer can provide considerable processing advantages with respect to the formation of selected devices and/or improved structures for particular devices.

In additional or alternative embodiments, the sheet can be cut in association with a support surface to form insulating gaps between the portions of the cut sheet. In some embodiments, cutting of the overcoat structure can be performed before and/or after the overcoat structure is separated from the substrate at a release layer. For relevant embodiments, the release layer can provide some protection of the substrate during cutting of the overcoat structure such that the substrate surface is not significantly damaged. In other embodiments, the semiconductor layer can be cut after deposition onto a permanent substrate to form structures for incorporation into a product. In further embodiments, the sheet is cut after transfer to a receiving substrate through the release by a release layer. The receiving substrate can be a permanent substrate or a temporary holding structure.

As noted above, in some embodiments, the silicon/germanium-based semiconductor sheet is formed onto of a substrate without a release layer so that the combined structure can be formed into a resulting product. For example, for the formation of a photovoltaic module, the substrate can be a silica glass possibly with a thin SiOₓN_{y} passivation layer onto which the silicon/germanium-based semiconductor sheet is formed. The exposed surface can be further processed with patterning and the like to form device for incorporation into the product. For example, the resulting structure can be processed into a full photovoltaic module.

An overcoat structure formed over a release layer generally can be subjected to one or more processing steps to prepare the material for incorporation into a particular device. These additional processing steps can be performed with the overcoat structure attached to the substrate, with the structure separated at the release layer, or with some of the processing steps performed with the structure attached to the substrate and some of the processing steps performed with the structure separated from the substrate. Etching or other post deposition patterning can be performed before, after and/or during any heat treatment step for consolidation/annealing.

Additional processing can involve association of the free standing thin layers with a holding surface. The holding surface may be a final location of the thin layers within a device for use, or the holding surface may be a temporary location to facilitate the performance of one or more processing steps. If the holding surface is temporary, the thin layers can be temporarily secured to the holding surface with an adhesive or the like. The association with a holding surface can mechanically stabilize the thin structure during particular processing steps.

For the formation of a photovoltaic cell as well as other appropriate devices, it is desirable to have texture on the top and/or bottom surfaces to increase the optical path lengths within the material. Texture can be introduced with a textured substrate with deposition over the textured substrate. Alternatively, texture can be introduced in a deposited surface in the deposition process or a subsequent etching or other surface modification step. The texturing can be random, pseudo-random, or ordered. The porosity of the release layer can also be used to impart a rough texture on subsequent layers.

The availability of thin, large area silicon/germanium-based semiconductor sheets provide for the production of large, high efficiency solar cells, displays as well as other devices based on these semiconductors sheets. Individual solar cells can be cut from a larger sheet as part of a solar cell panel formation. In a solar cell panel, there are a plurality of individual cells that are connected in parallel and/or in series. The cells connected in series increase the output voltage of the panel since the cells connected in series have additive potentials. Any cells connected in parallel provide increased current. Reasonably positioned cells on a panel can be electrically connected using appropriate electrical conductors. The wired photovoltaic panel can be appropriately connected then to an external electrical circuit.

To form a photovoltaic module, an additional layer, such as an under-layer or an associated layer, can be incorporated into a structure with one or more layers of silicon/germanium-based semiconductor alone and/or layers with dopants to form p-doped and/or n-doped semiconductor layers based on doped silicon/germanium. In general, a solar cell has a bulk semiconductor and doped domains that form portions of contacts associated with current collectors. A selected additional layer can function as a passivation layer on the front surface, rear surface or both. A passivation layer can also function as an antireflective layer.

Photovoltaic cells based on silicon, germanium, silicon carbide or alloys thereof incorporate a junction with a p-type semiconductor and an n-type semiconductor. The flow of current between current collectors of opposite polarity can be used useful work. The efficiency of the process depends in part on the recombination rate since electrons and holes can recombine before they flow to suitable current collectors. After recombination, the photo-generated electron-hole pair cannot be used for useful work. The processes described herein are suitable for the formation of desirable materials for photovoltaic cells. The use of thinner semiconductor structures results in a saving with respect to materials and corresponding costs. However, if the semiconductor is too thin, the silicon does not capture as much light. Thus, there are advantages in having a silicon/germanium-based semiconductor thickness no more than 100 microns and at least two microns.

In addition, the thin sheets of silicon/germanium-based semiconductor provide useful substrates for display components. In particular, the semiconductor sheet can be a substrate for the formation of thin film transistors and/or other integrated circuit components. Thus, the thin semiconductor sheets can be large format display circuits with one or more transistor associated with each pixel. The resulting circuits can replace structures formed by silicon on glass processes

In general, the semiconductor sheets described herein provide a cost effective approach to form a range of devices with a reduction in the use of material and a convenient processing format. The uniformity of the material and the speed of production are significant parameters for efficient and cost effective commercial production. The amenability of the semiconductor sheets to efficient forms of further processing make the sheets suitable for efficient formation of a range of integrated circuit and other structures.

### Product Synthesis within a Reactant Flow

Light reactive deposition, as with other flowing reactant systems, generally comprises a reactant delivery apparatus that directs a flow through a reaction chamber. Light reactive deposition is a valuable tool for the production of coating materials with a wide range of compositions and material properties as deposited or with additional processing. The reaction of the reactant flow takes place in the reaction chamber. The use of a radiation beam, e.g., a light beam, to drive the reaction can result in a localized reaction zone that leads to high uniformity of the product stream. Beyond the reaction zone, the flow can comprise a product composition (solid particles, molten particles, and/or vapor), unreacted reactants, reaction by-products and inert gases. The product flow can continue to a deposition surface at which at least a portion of the product composition is harvested from the flow as a coating.

Continuous supply of reactants to the flow and removal of product composition from the flow during the course of the reaction characterizes the reaction process within the flowing reactant system, although the reaction and/or the deposition can be interrupted at appropriate intervals, for example, to position substrates, alter reactant compositions or for other processing considerations and the like. Thus, there is a net flow that passes generally from an inlet nozzle connected to a reactant delivery apparatus to a vent generally connected through a pump. The net flow can be conceptually divided into a light reaction zone, a reactant flow up-stream from the light reaction zone and a product flow down-stream from the light reaction zone. These conceptual zones generally may not have sharply defined boundaries, although it is clear at some point that product is present to form a product stream/flow and that prior to reacting the reactants, no product is present in the reactant flow/stream.

Light reactive deposition can incorporate product composition versatility developed for the particle production within laser pyrolysis, a light driven flow process for particle synthesis. In particular, the versatility of forming particles with a range of particle compositions and structures can be adapted for the formation of coatings by light reactive deposition with a comparable range in compositions and structures.

Laser pyrolysis has become the standard terminology for flowing chemical reactions driven by an intense radiation, e.g., light, with rapid quenching of product particles after leaving a narrow reaction region defined by the radiation. The name, however, is a misnomer in the sense that radiation from non-laser sources, such as a strong, incoherent light or other radiation beam, can replace the laser. Also, the reaction is not a pyrolysis in the sense of a thermal pyrolysis. The laser pyrolysis reaction is not solely thermally driven by the exothermic combustion of the reactants. In fact, in some embodiments, laser pyrolysis reactions can be conducted under conditions where no visible light emissions are observed from the reaction, in stark contrast with pyrolytic flames.

The reaction conditions can determine the qualities of the compositions produced by light reactive deposition. The reaction conditions for light reactive deposition can be controlled relatively precisely in order to produce compositions and corresponding coatings with desired properties. In particular, the product flow characteristics influence the properties of the coating formed from the flow, although other factors, such as temperature of the substrate and coating parameters also influence the coating properties.

For example, the reaction chamber pressure, flow rates, composition and concentration of reactants, radiation intensity, radiation energy/wavelength, type and concentration of inert diluent gas or gases in the reaction stream, temperature of the reactant flow can affect the composition and other properties of the product flow, for example, by altering the time of flight of the reactants/products in the reaction zone and the availability of atomic species that recombine into product compositions in the product flow. Thus, in a particular embodiment, the specific reaction conditions can be controlled to yield desired product flow properties. The appropriate reaction conditions to produce a certain type of product flow generally depend on the design of the particular apparatus. Specific conditions used to produce selected coatings in particular apparatuses can be determined based on the general principles outlined herein along with appropriate empirical adjustments. Furthermore, some general observations on the relationship between reaction conditions and the resulting compositions can be made.

The velocity of the reactant stream can influence the density of the coating. Another significant factor in determining the coating parameters is the concentration of product composition within the product stream. Reducing the total concentration as well as the relative concentration of condensing product composition within the product flow results in a slower particle growth rate and smaller particles. The relative concentration of condensing product can be controlled by dilution with non-condensing, e.g., inert, compositions or by changing the pressure with a fixed ratio of condensing product to non-condensing compositions, with a reduction in pressure generally leading to reduced total concentration. Also, different product compositions have a tendency to coalesce at different rates within the product flow, which can correspondingly influence the coating density. In summary, the coating parameters can be selected to adjust the coating density.

Materials of interest generally include, for example, amorphous materials, crystalline materials and combinations thereof, although for silicon/germanium-based semiconductor materials crystalline materials are of particular interest. In light reactive deposition, the coating parameters, for example including the nature of the substrate surface, can influence the crystalline or amorphous structure of the coating.

To form a desired composition in the reaction process, one or more precursors supply the one or more metal/metalloid elements as well as any secondary elements that form the desired composition. While there is particular interest in depositing silicon/germanium-based semiconductor with or without dopant(s), associated layers and/or release layers can comprise compositions with selected secondary elements. Secondary elements include, for example, non-metal/metalloid elements, such as carbon, nitrogen, silicon, phosphorous and sulfur, that can be incorporated into the resulting product composition. The reactant stream generally comprises the desired metal and, additionally or alternatively, metalloid elements as well as any selected secondary elements to form a host material and, optionally, dopant(s)/additive(s) in appropriate proportions to produce particular product compositions.

The composition of the reactant stream can be adjusted along with the reaction condition(s) to generate desired product materials with respect to composition and properties. Based on the particular reactants and reaction conditions, the product compositions may not have the same proportions of metal/metalloid elements as the reactant stream since the elements may have different efficiencies of incorporation into the product, i.e., yields with respect to unreacted materials. However, the amount of incorporation of each element is a function of the amount of that element in the reactant flow, and the efficiency of incorporation can be empirically evaluated based on the teachings herein to obtain desired compositions. The designs of the reactant nozzles for radiation driven reactions described herein are designed for high yields with high reactant flows. Furthermore, additional appropriate precursor(s) can supply any desired dopant/additive element(s).

With respect to compositions, metalloids are elements that exhibit chemical properties intermediate between or inclusive of metals and nonmetals. Metalloid elements comprise silicon, germanium, boron, arsenic, and tellurium. Elements from the groups Ib, IIb, IIIb, IVb, Vb, VIIb, VIIb and VIIb are referred to as transition metals. In addition to the alkali metals of group I, the alkali earth metals of group II and the transition metals, other metals include, for example, aluminum, gallium, indium, thallium, tin, lead, bismuth and polonium. The non-metal/metalloid elements include hydrogen, the noble gases, carbon, nitrogen, oxygen, fluorine, phosphorous, sulfur, chlorine, selenium, bromine, and iodine.

Light reactive deposition can be performed with gas/vapor phase reactants. Many precursor compositions, such as metal/metalloid precursor compositions, can be delivered into the reaction chamber as a gas/vapor. Appropriate precursor compositions for gaseous delivery generally include compositions with reasonable vapor pressures, i.e., vapor pressures sufficient to get desired amounts of precursor gas/vapor into the reactant stream. The vessel holding liquid or solid precursor compositions can be heated (cooled) to increase (decrease) the vapor pressure of the precursor, if desired. Solid precursors generally are heated to produce a sufficient vapor pressure. A carrier gas can be bubbled through a liquid precursor to facilitate delivery of a desired amount of precursor vapor. Similarly, a carrier gas can be passed over the solid precursor to facilitate delivery of the precursor vapor. Alternatively or additionally, a liquid precursor can be directed to a flash evaporator to supply a composition at a selected vapor pressure. The use of a flash evaporator to control the flow of non-gaseous precursors provides a high level of control on the precursor delivery into the reaction chamber.

However, the use of exclusively gas/vapor phase reactants can be challenging with respect to identification of convenient types of precursor compositions for some elements. Thus, techniques have been developed to introduce aerosols containing precursors, such as metal/metalloid precursors, into reaction chambers for flowing light driven reactions. Improved aerosol delivery apparatuses for flowing reaction systems are described further in U.S. Pat. No. 6,193,936 to Gardner et al., entitled “Reactant Delivery Apparatuses,” incorporated herein by reference. These reactant delivery systems can be adapted for light reactive deposition. In some embodiments, the aerosol is entrained in a gas flow, which can comprise an inert gas(es) and/or a gaseous reactant(s).

Using aerosol delivery apparatuses, solid precursor compositions can be delivered by dissolving the compositions in a solvent. Alternatively, powdered precursor compositions can be dispersed in a liquid/solvent for aerosol delivery. Liquid precursor compositions can be delivered as an aerosol from a neat liquid, a multiple liquid dispersion or a liquid solution. Aerosol reactants can be used to obtain a significant reactant throughput. A solvent/dispersant can be selected to achieve desired properties of the resulting solution/dispersion. Suitable solvents/dispersants include water, methanol, ethanol, isopropyl alcohol, other organic solvents and mixtures thereof. The solvent should have a desired level of purity such that the resulting coatings have a desired purity level. Some solvents, such as isopropyl alcohol, are significant absorbers of infrared light from a CO₂ laser such that no additional light absorbing composition may be needed within the reactant stream if a CO₂ laser is used as a light source.

The precursor compositions for aerosol delivery are dissolved in a solution generally with a concentration in the range(s) greater than about 0.1 molar. Generally, increasing the concentration of precursor in the solution increases the throughput of reactant through the reaction chamber. As the concentration increases, however, the solution can become more viscous such that the aerosol may have droplets with larger sizes than desired. Thus, selection of solution concentration can involve a balance of factors in the selection of a suitable solution concentration. The use of aerosol reactants for light reactive deposition is described further in U.S. Pat. No. 6,849,334 to Home et al., entitled “Optical Materials And Optical Structures,” incorporated herein by reference.

Generally, the metal/metalloid elements can be delivered all as vapor, all as aerosol or as any combination thereof, especially for embodiments involving a plurality of metal/metalloid elements. If a plurality of metal/metalloid elements is delivered as an aerosol, the precursors can be dissolved/dispersed within a single solvent/dispersant for delivery into the reactant flow as a single aerosol. Alternatively, the plurality of metal/metalloid elements can be delivered within a plurality of solutions/dispersions that are separately formed into an aerosol. The generation of a plurality of aerosols can be helpful if convenient precursors are not readily soluble/dispersible in a common solvent/dispersant. The plurality of aerosols can be introduced into a common gas flow for delivery into the reaction chamber through a common nozzle. Alternatively, a plurality of reactant inlets can be used for the separate delivery of aerosol and/or vapor reactants into the reaction chamber such that the reactants mix within the reaction chamber prior to entry into the reaction zone.

The product compositions, in some embodiments, can further comprise one or more non-(metal/metalloid) elements. For example, an oxygen source can also be present in the reactant stream if the objective is to form an oxide. The oxygen source can be the metal/metalloid precursor itself if it comprises one or more oxygen atoms or a secondary reactant can supply the oxygen. The conditions in the reactor should be sufficiently oxidizing to produce the oxide materials. Similarly, the reactant stream can comprise a nitrogen source for the formation of a nitride.

Generally, secondary reactants can be used in some embodiments to alter the oxidizing/reducing conditions within the reaction chamber and/or to contribute non-metal/metalloid elements or a portion thereof to the reaction products. Suitable secondary reactants serving as an oxygen source for the formation of oxides include, for example, O₂, CO, N₂O, H₂O, CO₂, O₃ and the like and mixtures thereof. Molecular oxygen can be supplied as air. In some embodiments, the metal/metalloid precursor compositions comprise oxygen such that all or a portion of the oxygen in product particles is contributed by the metal/metalloid precursors. Suitable nitrogen sources include, for example, NH₃. Suitable carbon sources include, for example, C₂H₄ or a range of other hydrocarbons. Similarly, liquids used as a solvent/dispersant for aerosol delivery can similarly contribute secondary reactants to the reaction. In other words, if one or more metal/metalloid precursors comprise a desired secondary element and/or if a solvent/dispersant comprises oxygen, a separate secondary reactant may not be needed to supply a secondary element for product compositions.

To form an element in the product flow, the conditions in the reaction zone can be adjusted to be appropriately reducing. This can be accomplished through the balance of secondary reactants in view of the nature of the metal/metalloid precursors. Suitable reducing agents, such as H₂, C₂H₄ and the like can be included in the reactant flow. Additionally, elemental forms of silicon, germanium and other elements can be formed through decomposition reactions such as the decomposition of silane (SiH₄), germane (GeH₄) or the like.

Light reactive deposition can be performed with radiation at a variety of optical frequencies, using either a laser or other intense radiation source, such as an arc lamp. Convenient light sources operate in the infrared portion of the electromagnetic spectrum, although other wavelengths can be used, such as the visible, ultraviolet or infrared regions of the spectrum. Excimer lasers can be used as ultraviolet sources. CO₂ lasers are particularly useful sources of infrared light. Infrared absorber(s) for inclusion in the reactant stream include, for example, C₂H₄, isopropyl alcohol, NH₃, SF₆, SiH₄ and O₃. The radiation absorber(s), such as the infrared absorber(s), can absorb energy from the radiation beam and distribute the energy to the other reactants to drive the pyrolysis.

Generally, the energy absorbed from the light beam increases the temperature at a tremendous rate, many times the rate that heat generally would be produced by exothermic reactions under controlled conditions. In light reactive deposition, similar to the laser pyrolysis process, the reaction process is qualitatively different from the process in a combustion reactor where an energy source initiates a reaction, but the reaction is driven by energy given off by an exothermic reaction.

Thus, light reactive deposition is not a traditional pyrolysis since the reaction is not driven by energy given off by the reaction but by energy absorbed from a radiation beam. In particular, spontaneous reaction of the reactants generally does not proceed significantly, if at all, back down the reactant flow toward the nozzle from the intersection of the radiation beam with the reactant stream. If necessary, the flow can be modified such that the reaction zone remains confined. In a combustion reactor, there is generally no well-defined reaction zone with a boundary. The reaction zone is large and the residence time of the reactants is long. Lower thermal gradients are generally present in the combustion reactor.

In contrast, the laser/light driven reactions have extremely high heating rates. The product compositions generally depend on the radiation power in the reactions zone and the quantity of radiation absorbers in the flow. By controlling the composition of the reactant flow and the light intensity in the reaction zone, the reaction product can be reproducibly controlled. The effective temperature in the reaction zone can be controlled over a wide range, for example, in the range(s) from about 200° C.) to about 3000° C. In light reactive deposition, the reaction zone is primarily at the overlap of the light beam and the reactant stream, although the reaction zone may extend, for example, a few millimeters beyond the light beam, depending on the precise character of the reaction.

An inert shielding gas can be used to reduce the amount of reactant and product molecules contacting the reactant chamber components. Inert gases can also be introduced into the reactant stream as a carrier gas and/or as a reaction moderator. Appropriate inert gases generally include, for example, Ar, He and N₂.

The product production rate based on reactant delivery configurations described herein can yield product production rates in the range(s) from about 5 grams per hour of reaction product to about 10 kilograms per hour of desired reaction product. Specifically, using apparatuses described herein, coating can be accomplished at product production rates in the range(s) of up to at least about 10 g/h, in other embodiments in the range(s) of at least about 100 g/h, in further embodiments in the range(s) of at least about 250 g/h, in additional embodiments in the range(s) of at least about 1 kilogram per hour (kg/h) and in general up in the range(s) up to at least about 10 kg/h. A person of ordinary skill in the art will recognize that production rates intermediate between these explicit production rates are contemplated and are within the present disclosure. Exemplary rates of product production (in units of grams produced per hour) include in the range(s) of not less than about 5, 10, 50, 100, 250, 500, 1000, 2500, 5000, or 10000.

In general, these high production rates can be achieved while obtaining high coating uniformity and relatively high reaction yields, as evaluated by the portion of metal/metalloid nuclei in the flow that are incorporated into the product composition, a portion of which are incorporated into the dense coating. In general, the reaction product yield can be in the range(s) of at least about 30 percent based on the limiting reactant, in other embodiments in the range(s) of at least about 50 percent, in further embodiments in the range(s) of at least about 65 percent, in other embodiments in the range(s) of at least about 80 percent and in additional embodiments in the range(s) of at least about 95 percent based on the limiting reactant, generally a metal/metalloid nuclei in the reactant flow. A person of ordinary skill in the art will recognize that additional values of product production rates and yields within these specific values are contemplated and are within the present disclosure.

### Material Deposition

In light reactive deposition, a highly uniform flow of product composition is directed toward a substrate to be coated. The resulting coating can be formed as a coating across the substrate or patterned according to a selected structure. In addition, the coatings can be modified through subsequently processing, such as heat treatments or etching. The coating parameters can be varied to obtain the desired coating properties.

It may be desirable to form a powder coating using the light reactive deposition process. In light reactive powder coating deposition and the like, particles are deposited as a soot or snow, which is a very porous structure with a relatively low density. The particles result from a nucleation and quenching process within the flow. The powder coating may be desirable with respect to the further processing of the powder coating with respect to changing the composition or consolidating the material into a desired form. Furthermore, the formation of a powder coating may be useful for the formation of a release layer or the like. In some embodiments, the formation of a powder coating may be the result of using desired processing conditions within the reaction chamber.

In addition, light reactive dense deposition has surprisingly provided the ability to directly form denser coatings directly from a reactive flow. Furthermore, light reactive deposition has the advantage over other approaches in that the density can be controlled over a relatively large range of densities. In general, light reactive deposition can deliver product to the coating at very high rates at a particular density without sacrificing the quality of the coating with respect to uniformity and properties.

Light reactive deposition can offer additional advantages with respect to deposition of denser coatings of crystalline materials. With the deposition of particles, the short range order of the composition is fixed in the particle prior to interaction in the coating. Interactions between particles on the surface generally are not energetic enough to order the particles relative to their neighbors. The overall structure does not possess any long range order, even with crystalline particles, so that a polycrystalline material results. The reaction parameters in the flow determine whether or not the particles are amorphous or crystalline. The consolidation process to densify a powder coating formed by light reactive deposition may or may not be effective to alter the long range ordering of the material.

In light reactive deposition, the resulting coating can be amorphous (short range order only), polycrystalline (within domains) or crystalline. With respect to the coating process for forming a dense coating, deposition rate, product stream velocity, inert gas concentration, temperature of the substrate, temperature of the flow, relative orientation of the substrate with respect to the light reaction zone and other reaction parameters can be adjusted empirically to select the crystallinity properties of the resulting coating. Furthermore, the substrate structure can influence the coating structure. In general, with light reactive deposition for the deposition of any density coating, the post deposition processing can alter the form of the coating with respect to its crystallinity and other properties.

In the light reactive deposition process, to form a denser coating the substrate can be placed closer to the light reaction zone, the light intensity can be increased, and/or the flow velocity can be increased. For the production of silicon from silane, increasing the amount of silane in the reactant flow increases the flame temperature, which can lead to a denser coating. Also, the substrate can be heated to significant temperatures while remaining lower than the flow temperature of the deposited material. Other coating parameters may also affect the nature of the coating process. Along with these predictive trends with respect to coating parameters, for any particular reactor apparatus, the reaction parameters can be adjusted based on the teachings herein to perform dense coating deposition.

In general, light reactive deposition involves a flowing reactant stream that intersects with the radiation beam at a reaction zone where reaction products are subsequently deposited onto a substrate. In light reactive deposition, the coating of the substrate can be performed within the reaction chamber. A substrate intercepts flow from the reaction zone, directly capturing the product composition onto its surface.

A well-defined laser reaction zone can result in uniform product flow that results in uniform coating properties. The uniform product composition formulation results in uniform deposition and reproducible deposition. For vapor reactants, the use of a flash evaporator for reactant delivery can improve the uniformity of chemical delivery, which further improves the uniformity of the product flow and corresponding coating. Furthermore, in contrast with other methods that require the scanning of a substrate in two dimensions to form a layer, an elongated reactant inlet provides for the deposition of a uniform coating layer with one or few passes through the product stream such that a large number of stripes may not have to be stitched together.

In adapting this reactant delivery apparatus design for a coating process, the size of an elongated reactant inlet can be selected based on the size of the substrate to be coated. In some embodiments, the reactant inlet can be the same size or somewhat larger than the diameter or other dimension across the substrate, such as a width, such that the entire substrate can be coated in one pass through the product stream. In general, a reactor apparatus with flowing reactants having the elongated reactant inlet can be designed to reduce contamination of the chamber walls, to increase the production capacity and to make efficient use of resources. Furthermore, an appropriate flow of shielding gas can confine the reactants and products within a flow stream through the reaction chamber. The high throughput of reactants makes efficient use of the radiation (e.g., light) energy. The delivery of gaseous/vapor reactants and/or aerosol reactants can be adapted for delivery through an elongated inlet to form a sheet of flow through the reactor.

With light reactive deposition, the rate of production and/or deposition of the product composition can be varied substantially, depending on a number of factors (e.g., the starting materials being utilized, the desired reaction product, the reaction conditions, the deposition efficiency, and the like, and combinations thereof). Not all of the product composition generated is deposited on the substrate. Other factors affecting deposition efficiency include, for example, the product composition, temperature of the flow, substrate temperature and position and orientation of the substrate relative to the flow.

At moderate rates of relative substrate motion, coating efficiencies in the range(s) of not less than about 15 to about 20 percent can be achieved, i.e. about 15 to about 20 percent of the produced product composition is deposited on the substrate surface. Routine optimization can increase this deposition efficiency further. At slower relative motion of the substrate through the product stream, deposition efficiencies in the range(s) of at least about 40 percent and in additional embodiments in the range(s) of as high as 80 percent or more can be achieved. In general, with the achievable product production rates and deposition efficiencies, deposition rates can be obtained in the range(s) of at least about 5 g/hr, in other embodiments in the range(s) of at least about 25 g/hr, in further embodiments in the range(s) of at least from about 100 g/hr to about 5 kg/hr and in still other embodiment in the range(s) from about 250 g/hr to about 2.5 kg/hr. A person of ordinary skill in the art will recognize that coating efficiencies and deposition rates between these explicit rates are contemplated and are within the present disclosure. Exemplary rates of product deposition (in units of grams deposited per hour) include in the range(s) of not less than about 0.1, 0.5, 1, 5, 10, 25, 50, 100, 250, 500, 1000, 2500, or 5000.

Alternatively or additionally, the rate of the movement of the substrate and the product flow relative to each other can vary substantially, depending on the desired specifications for the coated substrate. In particular, for apparatus designs based on an actuator arm moving a substrate through the product stream within a reaction chamber, as described herein, the rate for moving a substrate can vary in the range(s) of at least about 0.001 centimeters (cm) per second, in other embodiments at least about 0.05 cm per second, in further embodiments, from about 1 cm per second to about 20 centimeters per second, or even more. A person of ordinary skill in the art will recognize that additional ranges within these explicit ranges are contemplated and are encompassed within the present disclosure. Further, in another embodiment, the rate can be measured on a scale relative to the substrate being coated, and can vary in the range(s) from about 0.05 substrates per minute to about 1 substrate per second.

Due to the high rates and coating uniformity, light reactive deposition is well suited to the coating of large substrates. In some embodiment, the process can be used to form materials for an entire photovoltaic panel in association with a single substrate. A width of coated substrate can be at least about 30 centimeters (cm), in further embodiments at least about 50 cm, in additional embodiments at least about 100 cm, and in other embodiment from about 200 cm to 2000 cm. In some embodiments, the area can be at least about 900 square centimeters (cm²), in other embodiments at least about 1,500 cm², in further embodiments at least about 2,000 cm², and in other embodiments from about 2,500 to about 50,000 cm². A person of ordinary skill in the art will recognize that additional ranges of widths and areas within the explicit ranges above are contemplated and are within the present disclosure.

A coating formed by light reactive deposition generally can have a density within a fairly broad range. Powder coatings can be formed with densities less than about 55%. As used herein, a dense coating refers to a coating with a density that is at least about 65%, in further embodiments at least about 75%, in additional embodiments at least about 85%, and in other embodiments at least about 95% of the full density of the coating material in a fully densified bulk form. Also, in some embodiments the dense coating directly applied with light reactive dense deposition has approximately a full, i.e., 100%, density as deposited. The dense coating may or may not be porous. Generally, the presence of a porous character is correlated with the density of the coating. The coating porosity can be evaluated with a gas through determining if any gas is absorbed into the materials. The BET surface area measurement process for particulates can be adapted for this purpose. Alternatively, another approach for the measurement of porosity of solid surfaces is described, for example, in U.S. Pat. No. 5,373,727 to Heller et al., entitled “Miniporopermeameter,” incorporated herein by reference.

For appropriate embodiments using a sheet of product flow, a selected rate of relative substrate motion generally is a function of the selected deposition rate and the desired coating thickness as limited by the movement the substrate at the desired rate while obtaining desired coating uniformity. In embodiments in which the substrate is swept through the product stream, the substrate can be moved relative to a fixed nozzle, and/or the nozzle can be moved relative to a fixed substrate. These coating rates by light reactive deposition are dramatically faster than rates that are achievable by competing methods at the same coating uniformity and thickness. As a particular example for reference, at a product production rate of about 10 kg/hr, an eight-inch circular wafer can be coated with a thickness of about 5 microns of dense coating in approximately one second even at a deposition efficiency of only about 7.5 percent, assuming a powder density of about 60% of the bulk density. A person of ordinary skill in the art can calculate with simple geometric principles any one of the following variables based on one or more of the other variables from the group of a coating rate, the deposition rate, the desired thickness and the density of coating on the substrate.

Furthermore, the rapid production rate can be advantageously used to form a plurality of coatings with or without additional treatments between coatings. Each coating can cover an entire layer or a portion of a layer. Compositions can be changed within a layer or between layers. When changing compositions significantly between layers, it may be desirable to wait a few seconds for the product stream to stabilize prior to initializing coating.

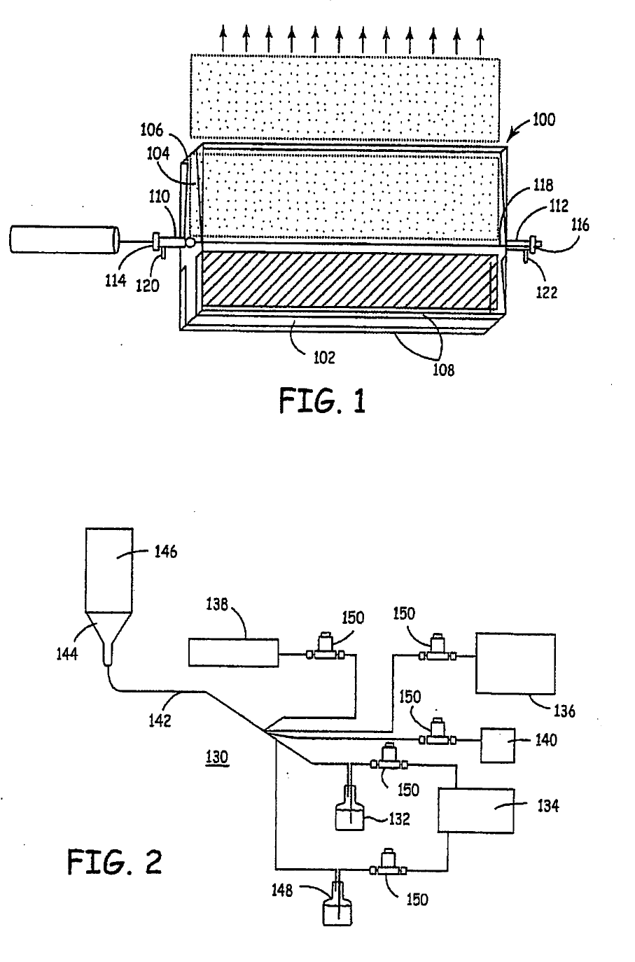

The design of a representative elongated reaction chamber 100 for generating a sheet of product flow is shown schematically in FIG. 1. This chamber is shown without displaying any coating components for simplicity with respect to other reactor components and can be adapted for coating as described further below with respect to related coating embodiments. A reactant inlet 102 leads to main chamber 104. Reactant inlet 102 conforms generally to the shape of main chamber 104. Main chamber 104 comprises an outlet 106 along the reactant/product stream for removal of undeposited product materials, any unreacted gases and inert gases. Shielding gas inlets 108 are located on both sides of reactant inlet 102. Shielding gas inlets are used to form a blanket of inert gases on the sides of the reactant stream to inhibit contact between the chamber walls and the reactants or products.

The dimensions of elongated reaction chamber 104 and reactant inlet 102 can be designed for highly efficiency product composition production. Reasonable lengths for reactant inlet 102, when used with a CO₂ laser with a power in the several kilowatt range, are from roughly about 5 mm to about 1 meter. The reaction zone is located within the reaction chamber in the vicinity of the intersection of the reactant flow with the light beam path.

Tubular sections 110, 112 extend from the main chamber 104. Tubular sections 110, 112 hold windows 114, 116, respectively, to define a light beam path 118 through the reaction chamber 100. Tubular sections 110, 112 can comprise inert gas inlets 120, 122 for the introduction of inert gas into tubular sections 110, 112.

Reactant inlet 102 is generally connected to a reactant delivery system. Referring to FIG. 2, an embodiment 130 of a reactant delivery apparatus comprises a source 132 of a precursor compound, which can be a liquid, solid or gas. For liquid or solid reactants, an optional carrier gas from one or more carrier gas sources 134 can be introduced into precursor source 132 to facilitate delivery of the reactant. Precursor source 132 can be a liquid holding container, a solid precursor delivery apparatus or other suitable container. The carrier gas from carrier gas source 134 can be, for example, an infrared absorber, an inert gas or mixtures thereof. In alternative embodiments, precursor source 132 is a flash evaporator that can deliver a selected vapor pressure of precursor without necessarily using a carrier gas. A flash evaporator can deliver a selected partial pressure of a precursor vapor into the reaction chamber, and other components leading to the reaction chamber can be heated, if appropriate, to reduce or eliminate condensation of the vapor prior to entry into the reaction chamber. Thus, a plurality of flash evaporators can be used to deliver precisely a plurality of vapor reactants into the reaction chamber.

The gases/vapors from precursor source 132 can be mixed with gases from infrared absorber source 136, inert gas source 138 and/or gaseous reactant source 140 by combining the gases/vapors in a single portion of tubing 142. The gases/vapors are combined a sufficient distance from the reaction chamber such that the gases/vapors become well mixed prior to their entrance into the reaction chamber. The combined gas/vapor in tube 142 passes through a duct 144 into channel 146, which is in fluid communication with a reactant inlet such as 102 in FIG. 1.

An additional reactant precursor can be supplied as a vapor/gas from second reactant source 148, which can be a liquid reactant delivery apparatus, a solid reactant delivery apparatus, a flash evaporator, a gas cylinder or other suitable container or containers. As shown in FIG. 2, second reactant source 148 delivers an additional reactant to duct 144 by way of tube 142. Alternatively, second reactant source can deliver the second reactant into a second duct such that the two reactants are delivered separately into the reaction chamber where the reactants combine at or near the reaction zone. Thus, for the formation of complex materials and/or doped materials, a significant number of reactant sources and, optionally, separate reactant ducts can be used for reactant/precursor delivery. For example, as many as 25 reactant sources and/or ducts are contemplated, although in principle, even larger numbers could be used. Mass flow controllers 150 can be used to regulate the flow of gases/vapors within the reactant delivery system of FIG. 2. Additional reactants/precursors can be provided similarly for the synthesis of complex materials.

As noted above, the reactant stream can comprise one or more aerosols. The aerosols can be formed within the reaction chamber or outside of the reaction chamber prior to injection into the reaction chamber. If the aerosols are produced prior to injection into the reaction chamber, the aerosols can be introduced through reactant inlets comparable to those used for gaseous reactants, such as reactant inlet 102 in FIG. 1. For the formation of complex material, additional aerosol generators and/or vapor/gas sources can be combined to supply the desired composition within the reactant stream.

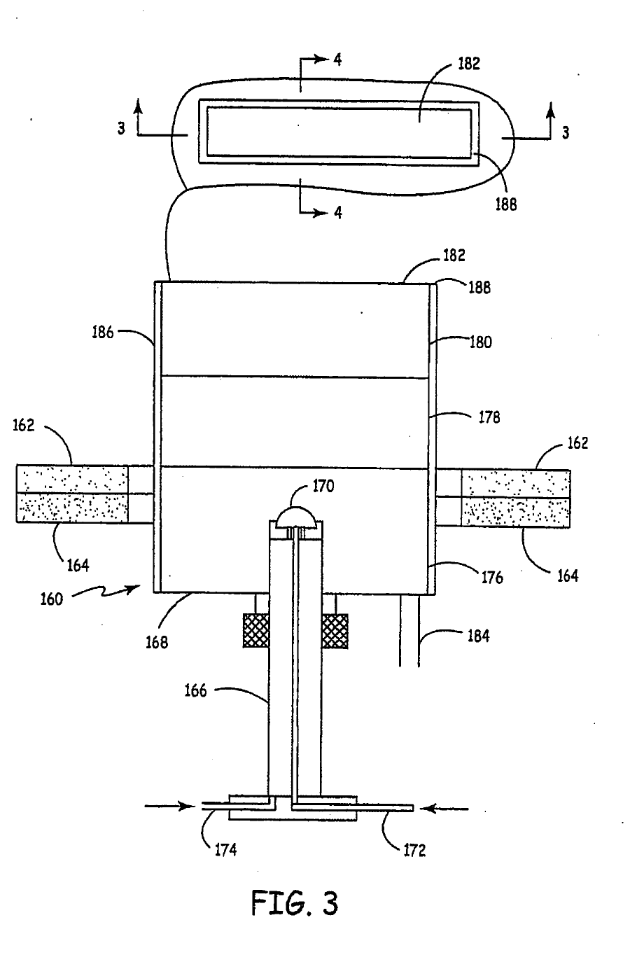

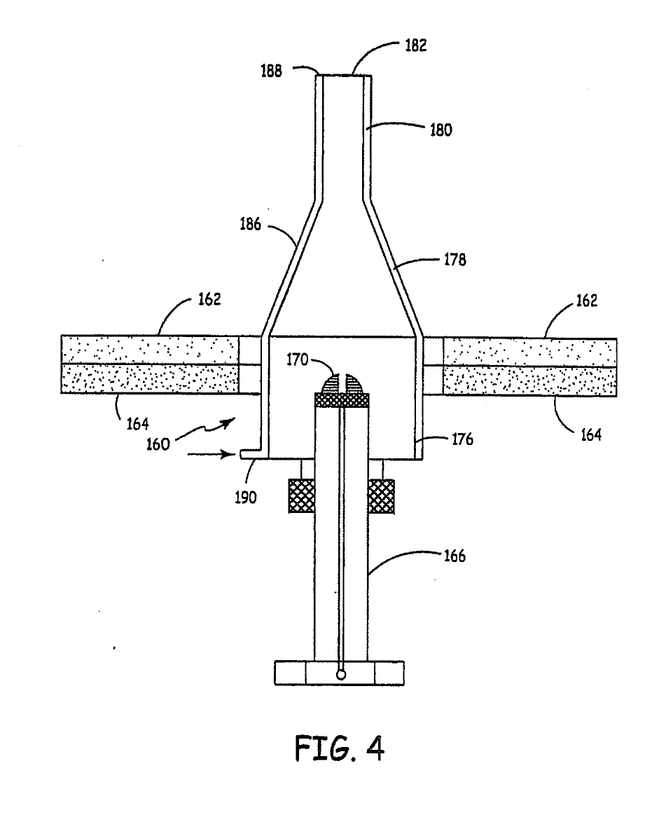

An embodiment of a reactant delivery nozzle configured to deliver an aerosol reactant is shown in FIGS. 3 and 4. Inlet nozzle 160 connects with a reaction chamber at its lower surface 162. Inlet nozzle 160 comprises a plate 164 that bolts into lower surface 162 to secure inlet nozzle 160 to the reaction chamber. Inlet nozzle 160 comprises an inner nozzle 166 and an outer nozzle 168. Inner nozzle 166 can have, for example, a twin orifice internal mix atomizer 170 at the top of the nozzle. Suitable gas atomizers are available from Spraying Systems, Wheaton, Ill. The twin orifice internal mix atomizer 170 has a fan shape to produce a thin sheet of aerosol and gaseous compositions. Liquid is fed to the atomizer through tube 172, and gases for introduction into the reaction chamber are fed to the atomizer through tube 174. Interaction of the gas with the liquid assists with droplet formation.

Outer nozzle 168 comprises a chamber section 176, a funnel section 178 and a delivery section 180. Chamber section 176 holds the atomizer of inner nozzle 166. Funnel section 178 directs the aerosol and gaseous compositions into delivery section 180. Delivery section 180 leads to a rectangular reactant opening 182, shown in the insert of FIG. 3. Reactant opening 182 forms a reactant inlet into a reaction chamber for light reactive deposition. Outer nozzle 168 comprises a drain 184 to remove any liquid that collects in the outer nozzle. Outer nozzle 168 is covered by an outer wall 186 that forms a shielding gas opening 188 surrounding reactant opening 182. Inert shielding gas is introduced through tube 190. Additional embodiments for the introduction of an aerosol with one or more aerosol generators into an elongated reaction chamber is described in U.S. Pat. No. 6,193,936 to Gardner et al., entitled “Reactant Delivery Apparatuses,” incorporated herein by reference.

In general, the substrate is mounted to receive product compositions flowing from the reaction zone. The distance from the reaction zone to the substrate can be selected to yield desired coating results. In some embodiments, the substrate is placed in the range(s) from no more than about 15 centimeters (cm) coaxial to the reactant flow vector measured from the radiation beam edge, i.e., the downstream locus of points where the radiation intensity is a factor of 1/e² of the maximum beam intensity, in other embodiments in the range(s) from about 0.5 mm to 10 cm, and in further embodiments in the range(s) from about 2 mm to about 8 cm. A person of ordinary skill in the art will understand that additional ranges within the explicit ranges of substrate distances are conceived and are within the present disclosure. The coating process generally is dynamic in the sense that a well defined product flow can be directed to desired substrate locations.

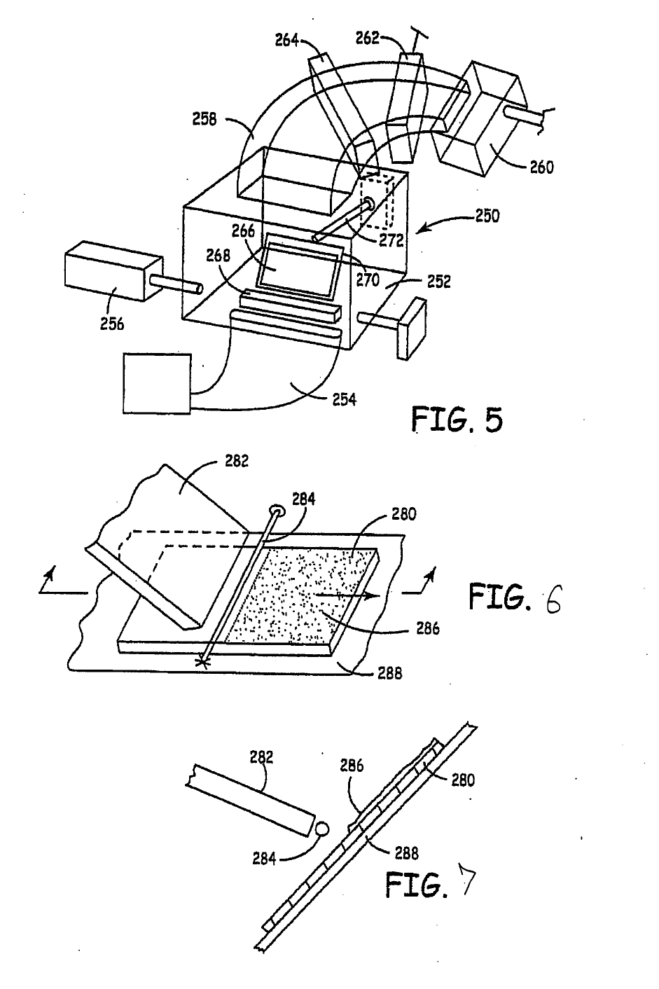

A representative apparatus 250 to perform substrate coating within the reaction chamber is shown schematically in FIG. 5. The reaction/coating chamber 252 is connected to a reactant supply system 254, a radiation source 256 and an exhaust 258. Exhaust 258 can be connected to a pump 260, although the pressure from the reactant stream itself can maintain flow through the system. A valve 262 can be used to control the flow to pump 260. Valve 262 can be used to adjust the pumping rate and the corresponding chamber pressures. A collection system, filter, scrubber or the like 264 can be placed between chamber 252 and pump 260 to remove product compositions that did not get coated onto the substrate surface.

Substrate 266 can contact flow from a reaction zone 268 to coat the substrate with product compositions. Substrate 266 can be mounted on a stage, conveyor, or the like 270 to sweep substrate 266 through the flow. Specifically, stage 270 can be connected to an actuator arm 272 or other motorized apparatus to move stage 270 to sweep the substrate through the product stream. Various configurations can be used to sweep the coating across the substrate surface as the product leaves the reaction zone. A shown in FIG. 5, actuator arm 272 translates stage 270 to sweep substrate 266 through the product stream. Stage 270 can comprise thermal control features that provide for the control of the temperature of the substrates on stage 270. Other designs for a stage, conveyor or the like can be used to sweep the substrate through the product flow.

FIG. 5 shows reactants delivered from the bottom so that flow through the reaction chamber goes from bottom to top. However, it can be desirable to flow the reactants form the top to have flow from the top down. In a top down configuration, gravity can assist with the deposition process.

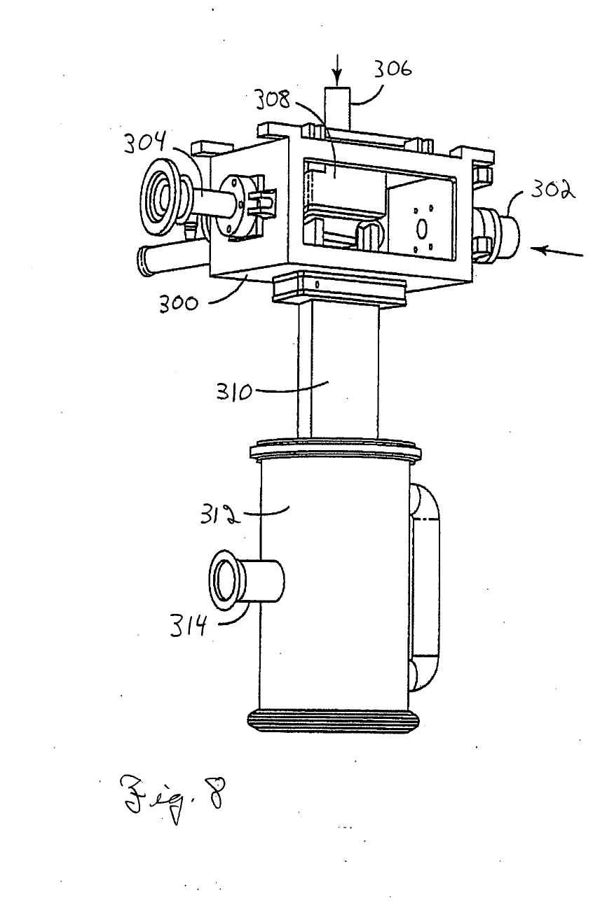

Another embodiment is shown in an expanded view in FIGS. 6 and 7. A substrate 280 moves relative to a reactant nozzle 282, as indicated by the right directed arrow. Reactant nozzle 282 is located just above substrate 280. An optical path 284 is defined by suitable optical elements that direct a light beam along path 284. Optical path 284 is located between nozzle 282 and substrate 280 to define a reaction zone just above the surface of substrate 280.

Referring to FIGS. 6 and 7, a coating 286 is formed as the substrate is scanned past the reaction zone. In general, substrate 280 can be carried on a conveyor/stage 288. Conveyor/stage 288 can be connected to an actuator arm, as shown in FIG. 5. In alternative embodiments, rollers and a motor, a continuous belt conveyor, or any of a variety of design, comprising known designs, for translating a substrate can be used to carry the substrate.

In some embodiments, the position of conveyor 288 can be adjusted to alter the distance from substrate 286 to the reaction zone. Changes in the distance from substrate to the reaction zone correspondingly alter the temperature of the product stream striking the substrate. The temperature of the product flow striking the substrate generally alters the properties of the resulting coating. The distance between the substrate and the reaction zone can be adjusted empirically to produce desired coating properties, such as coating density. In addition, the stage/conveyor supporting the substrate can comprise thermal control features such that the temperature of the substrate can be adjusted to higher or lower temperatures, as desired.

Another embodiment of a light reactive deposition apparatus is shown in FIGS. 8-10. Referring to FIG. 8, process chamber 300 includes a light tube 302 connected to a CO₂ laser and a light tube 304 connected to a beam dump (not shown). An inlet tube 306 connects with a precursor delivery system that delivers vapor reactants and carrier gases. Inlet tube 306 leads to process nozzle 308. An exhaust transport tube 310 connects to process chamber 300 along the flow direction from process nozzle 308. Exhaust transport tube 310 leads to a product filtration chamber 312. Product filtration chamber 312 connects to a pump at pump connector 314.

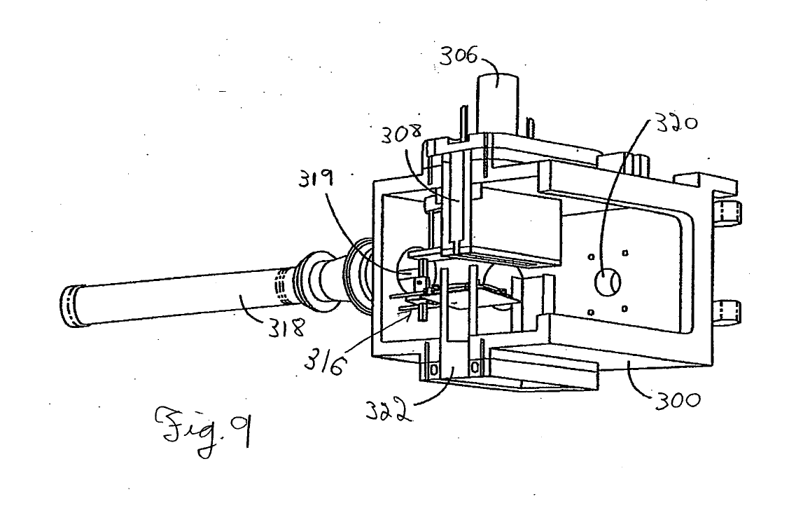

An expanded view of process chamber 300 is shown in FIG. 9. A substrate carrier 316 supports a substrate above process nozzle 308. Substrate carrier 316 is connected with an arm 318, which translates the substrate carrier to move the substrate through the product stream emanating from the reaction zone where the light beam intersects the precursor stream from process nozzle 308. Arm 318 comprises a linear translator 319 that is shielded with a tube. A light entry port 320 is used to direct a light beam between process nozzle 308 and the substrate. In this embodiment, unobstructed flow from process nozzle would proceed directly to exhaust nozzle 322, which leads to exhaust transport tube 310.

An expanded view of substrate carrier 316 and process nozzle 308 is shown in FIG. 10. The end of process nozzle 308 has an opening for precursor delivery 324 and a shielding gas opening 326 around precursor opening to confine the spread of precursor and product flow. Substrate carrier 316 includes a support 328 that connects to process nozzle 308 with a bracket 330. A wafer 332 can be held in a mount 334 such that wafer 332 slides within mount 334 along tracks 336 to move wafer 332 into the flow from the reaction zone. Backside shield 338 prevents uncontrolled deposition of product composition on the back of wafer 332. Tracks 336 connect to linear 319.

For any of the coating configurations, the intersection of the flow with the substrate deflects the trajectory of the flow. Thus, it may be desirable to select the position of the reaction chamber outlet to account for the change in direction of the flow due to the substrate, rather than placing the outlet in a direct line from the reactant inlet. For example, it may be desirable to alter the chamber design to direct the reflected flow to the outlet and/or to change the position of the outlet accordingly.

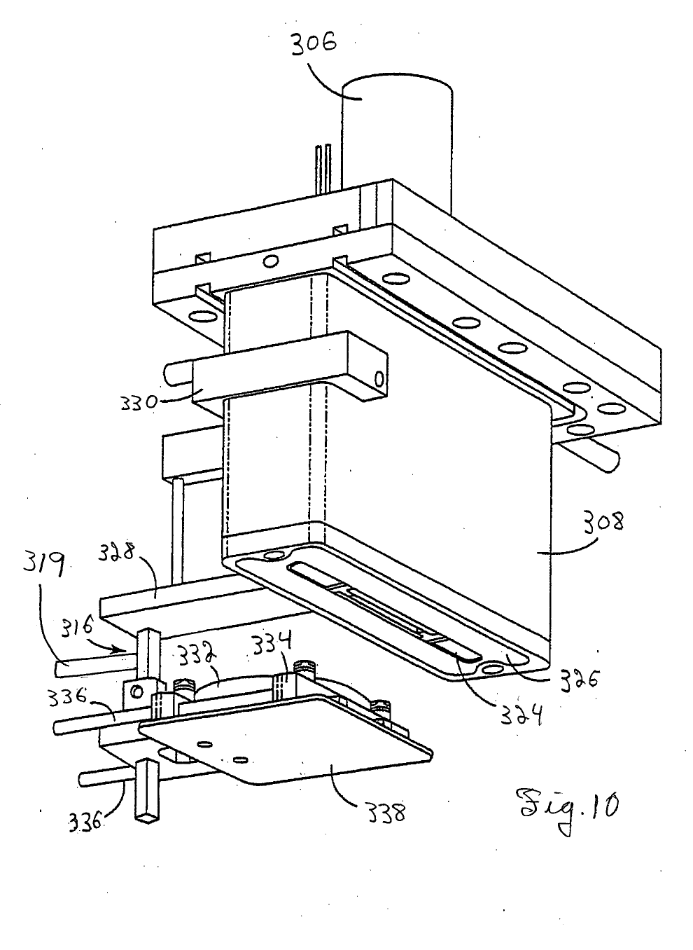

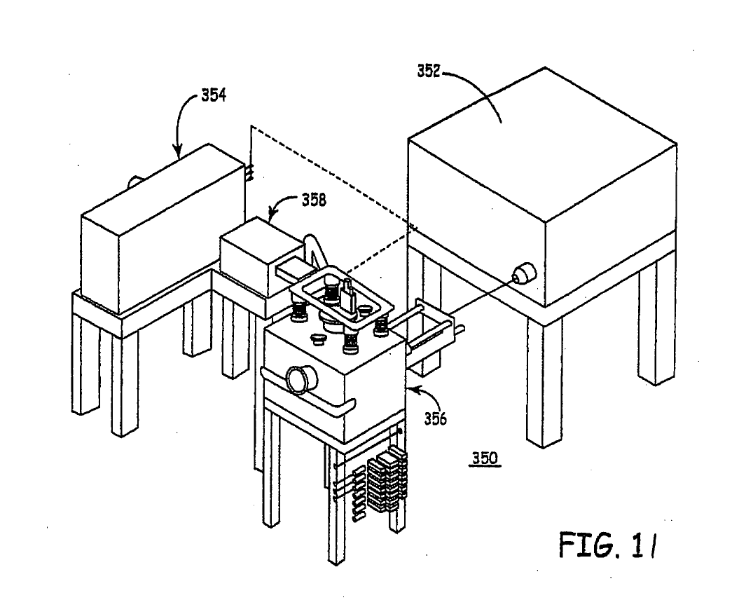

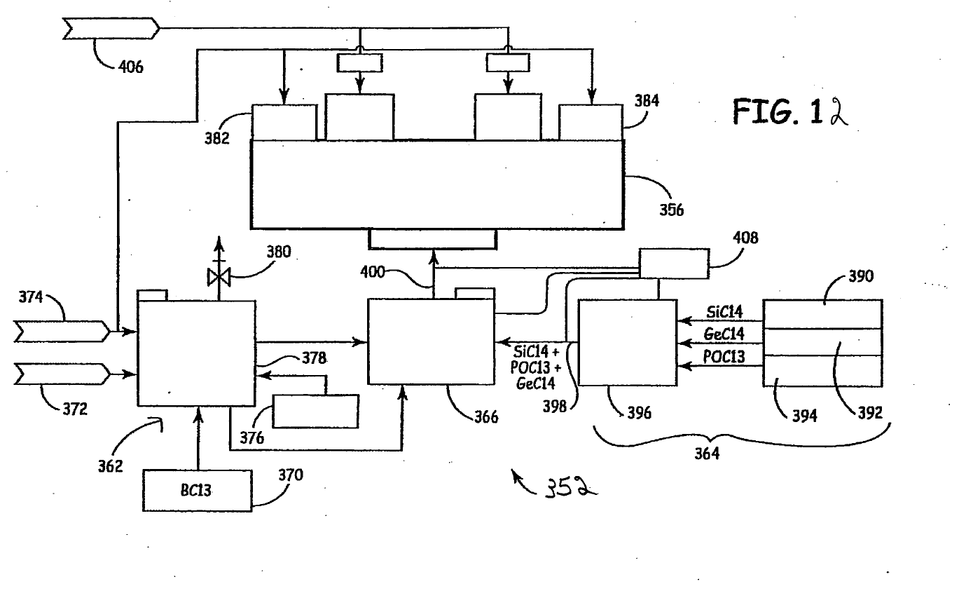

Another specific embodiment of a light reactive deposition apparatus is shown in FIG. 11. Apparatus 350 comprises a CO₂ laser light source 352, a reactant delivery system 354, a reaction chamber 356, and exhaust system 358. Referring to FIG. 12, a schematic diagram is shown with some specific reactants for forming doped silicon/germanium, although other reactants can be further included or substituted based on the disclosure herein.

As shown in FIG. 12, reactant delivery system 352 comprises a gas delivery subsystem 362 and a vapor delivery subsystem 364 that join a mixing subsystem 366. Gas delivery subsystem 362 can comprise one or more gas sources, such as a gas cylinder or the like for the delivery of gases into the reaction chamber. As shown in FIG. 12, gas delivery subsystem 362 comprises boron precursor source 370, an oxygen source precursor 372, an inert gas source 374, and a light absorbing gas source 376. The gases combine in a gas manifold 378 where the gases can mix. Gas manifold can have a pressure relief valve 380 for safety. Inert gas source 374 can be also used to supply inert gas within the chamber adjacent the windows/lenses 382, 384 used to direct light from an external light source into chamber 356.

Vapor delivery subsystem 364 comprises a plurality of flash evaporators 390, 392, 394. Each flash evaporator can be connected to a liquid reservoir to supply liquid precursor in suitable quantities. Suitable flash evaporators are available from, for example, MKS Equipment or can be produced from readily available components. As shown in FIG. 12, flash evaporators 390, 392, 394 respectively supply a silicon precursor, a germanium precursor and a phosphorous precursor. The flash evaporators can be programmed to deliver a selected partial pressure of the particular precursor. The vapors from the flash evaporator are directed to a manifold 396 that directs the vapors to a common feed line 398. The vapor precursors mix within common feed line 398.

The gas components from gas delivery subsystem 362 and vapor components from vapor delivery subsystem 364 are combined within mixing subsystem 366. Mixing subsystem 366 can be a manifold that combines the flow from gas delivery subsystem 362 and vapor delivery subsystem 364. In the mixing subsystem 366, the inputs can be oriented to improve mixing of the combined flows of different vapors and gases at different pressures. The mixing block has a slanted termination to reduce backflow into lower pressure sources. A conduit 400 leads from mixing subsystem 366 to reaction chamber 356.

A separate shielding gas system 406 can be used to delivery inert shielding gas to a moving nozzle assembly in reaction chamber 356, although inert gas source 374 can be used to supply inert gas to an external section of the moving nozzle. The shielding gas from the external sections of the nozzle serves as a guide for the reactant precursor stream into the light reaction zone.

A heat controller 408 can be used to control the heat through conduction heaters or the like throughout the vapor delivery subsystem, mixing system 366 and conduit 400 to reduce or eliminate condensation of precursor vapors. A suitable heat controller is model CN132 from Omega Engineering (Stamford, Conn.). Overall precursor flow can be controlled/monitored by a DX5 controller from United Instruments (Westbury, N.Y.). The DX5 instrument can be interfaced with mass flow controllers (Mykrolis Corp., Billerica, Mass.) controlling the flow of one or more vapor/gas precursors. The automation of the system can be integrated with a controller from Brooks-PRI Automation (Chelmsford, Mass.).

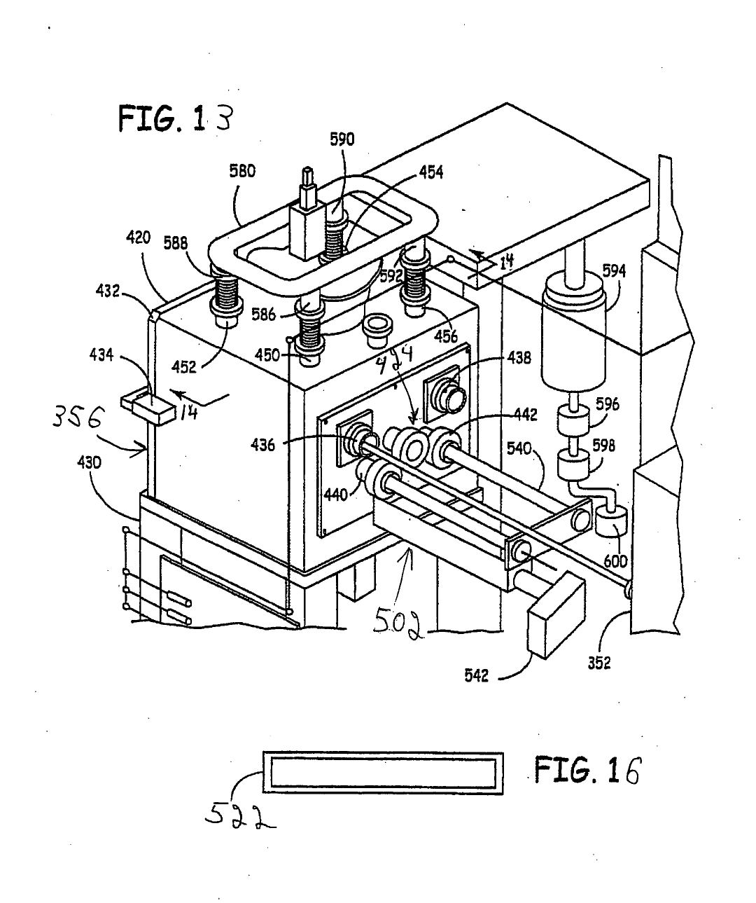

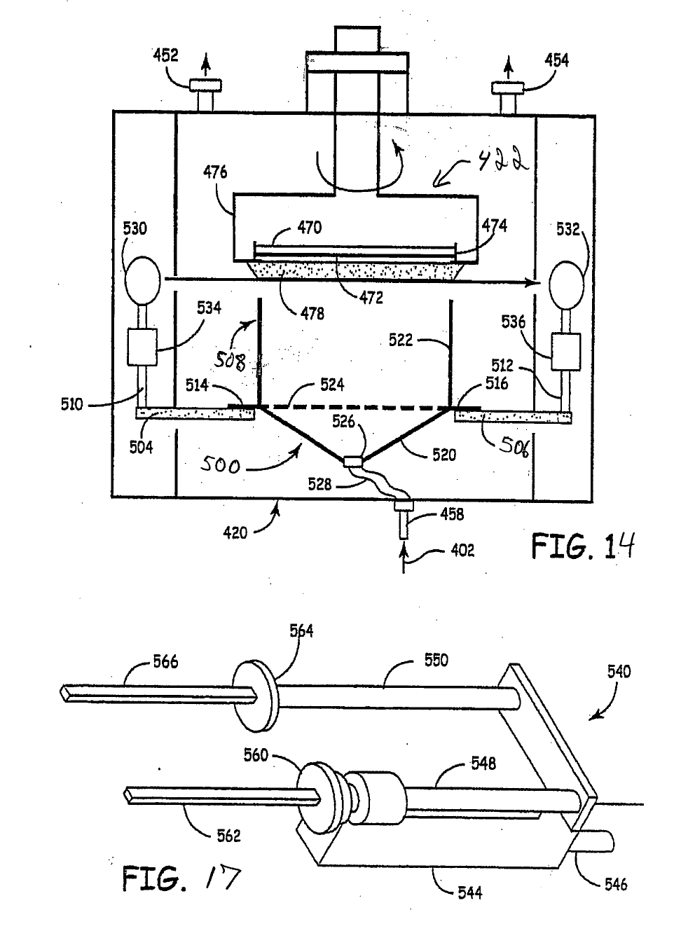

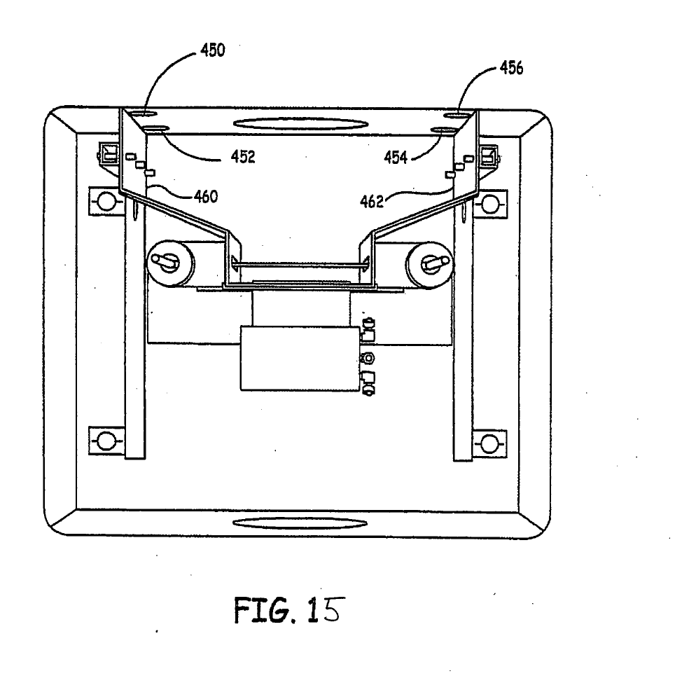

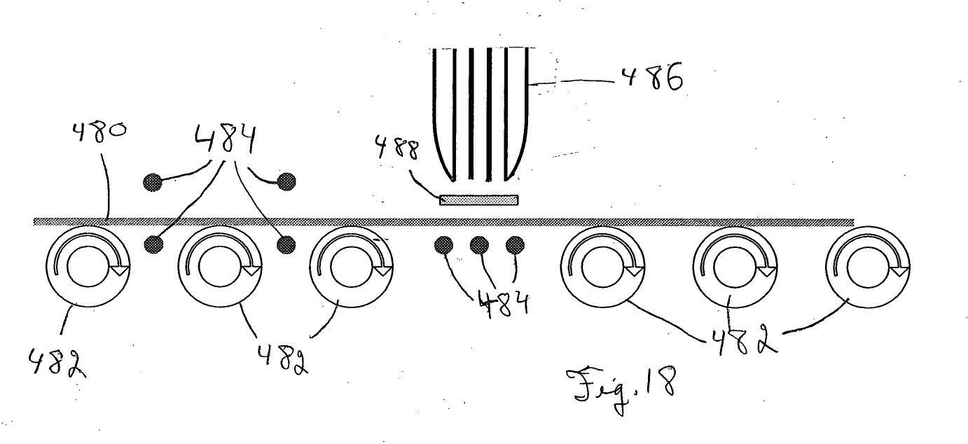

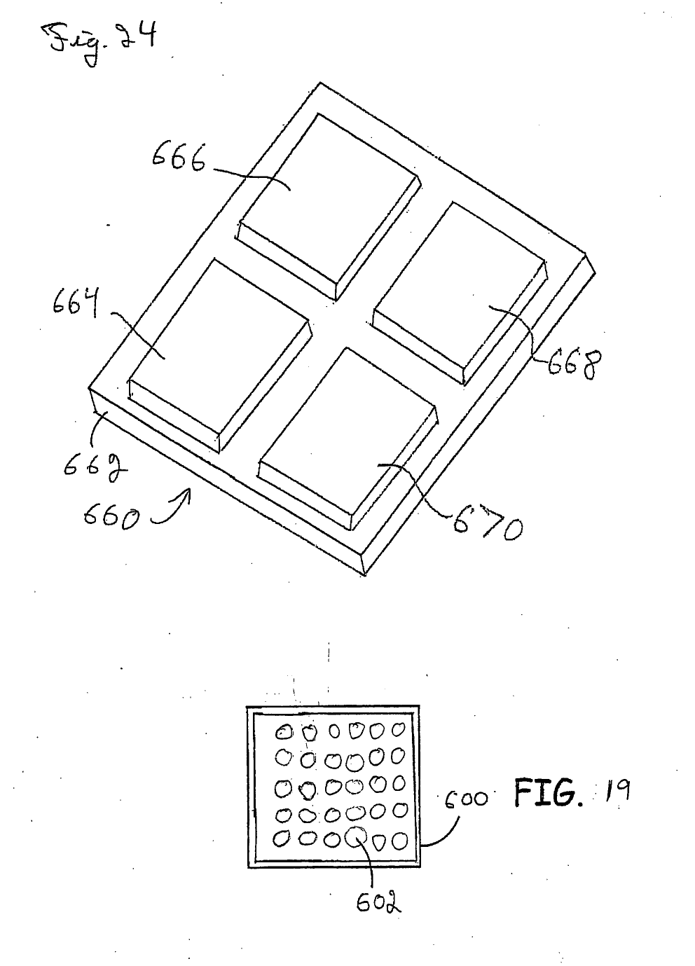

Referring to FIGS. 13 and 14, reaction chamber 356 comprises a chamber structure 420, a wafer mount 422 and a moving nozzle system 424. Chamber structure 420 rests on a stand 430. Chamber structure 420 comprises a hatch 432 that secures closed with a latch 434. Chamber structure 420 also comprises a window 436 that is positioned to receive light from laser 352, and a window 438 for exiting light, which can be connected to a power meter (not shown). Window 436 can include a lens, such as a cylindrical lens. Chamber structure 420 interfaces with moving nozzle system 424 through sealed ports 440, 442. Chamber structure 420 interfaces with exhaust system 356 through four vents 450, 452, 454, 456. Referring to FIG. 14, chamber structure 420 further comprises a reactant port 458 that connects reactant delivery system 352 (FIG. 12) at conduit 402 with moving nozzle system 424. Referring to FIG. 15, baffles 460, 462 guide flow to vents 450, 452, 454, 456. Referring to FIG. 14, two-position shutter 478 can be selectively opened and closed to expose (open) or shield (closed) wafer 472.

Referring to FIGS. 13-15 moving nozzle system 424 comprises a moving mount 500 and drive system 502. Moving mount 500 comprises a mounting bracket 504, 506, nozzle 508 and mirror mounts 510, 512. Mounting brackets 504, 506 connect nozzle 508 and mirror mounts 510, 512. Nozzle 508 connects with mounting brackets 504, 506 at flanges 514, 516. Nozzle 508 also comprises funnel section 520 and rectangular section 522 with a metal grid 524. Funnel section expands from an orifice 526 to rectangular section 522. A flexible tube 528 connects orifice 526 with reactant port 458, such that the nozzle remains connected to the reactant delivery system as the nozzle moves. In a particular embodiment, rectangular section has a rectangular cross section with dimensions of 0.08 inches×4.65 inches as shown schematically a top view in FIG. 16, although other ratios of lengths or widths can be used. Metal grid 524 divides the flow from funnel section 520 to provide a more uniform flow in rectangular section 522. Nozzle designs for flowing reactors are described further in U.S. Pat. No. 6,919,054 to Gardner et al., entitled “Reactant Nozzles Within Flowing Reactors,” incorporated herein by reference. Referring to FIG. 14, mirror mounts 510, 512 extend respectively from mounting brackets 504, 506. Mirror mounts 510, 512 also comprise respectively mirrors 530, 532, which can be, for example, parabolic or cylindrically focusing copper mirrors. The mirrors can be water cooled. The light path between mirrors 530, 532 is shown with an arrow in FIG. 14. Mirror mounts 510, 512 connect with drive system 502 at support brackets 534, 536.

Referring to FIG. 13, drive system 502 comprises a dual linear manipulator 540 and a motor 542. In one embodiment, the motor moves a magnet that couples to the manipulator arm such that it controls the movement of the manipulator arm. The movement of the manipulator arm results in the movement of the bracket/nozzle system. The velocity and acceleration throughout the motion can be precisely controlled. A suitable motor is a model P22NRXB-LNN—NF-00 from Pacific Scientific (Rockford, Ill.). Referring to FIG. 17, dual linear manipulator 540 comprises a motor interface bracket 544 with a motor interface rod 546. Motor interface bracket connects with a first shaft 548 and a second shaft 550, as shown in FIG. 17. First shaft 548 comprises stop 560 and a first support shaft 562, and second shaft 550 comprises a stop 564 and a second support shaft 566. Referring to FIGS. 13 and 17, stops 560, 564 limit the motion of dual linear manipulator 540 when stops 560, 564 contact ports 440, 442. Support shafts 562, 566 slide through ports 440, 442, respectively, which are sealed with an o-ring. Furthermore, inert gas can be flowed from the back of the translator arm to purge the chamber and to keep the arms cleaner with respect to product compositions. Support shafts 562, 566 connect with moving nozzle system 424 at support brackets 534, 536, respectively, as shown in FIG. 14.

Support shafts support moving nozzle system 424. Furthermore, chamber 420 can comprise a support track to help support the moving nozzle system. For example, a guide rail can be included on each side of the chamber. The guide rails help to ensure uniformity during translation. In some embodiments, the arm comprises a flanged rulon bearing that rolls over the guiding rail.

In one embodiment, exhaust system 358 comprises a conduit 580, as shown schematically in FIG. 13. Conduit 580 comprises channels 586, 588, 590, 592 that connect respectively with vents 450, 452, 454, 456. Exhaust system 358 can further comprise a filter 594, two in-line Sodasorb® (W. R. Grace) chlorine traps 596, 598 and a pump 600. Conduit 580 connects with filter 594, and Sodasorb® traps 596, 598 can be placed between filter 594 and pump 600 to prevent chlorine from damaging the pump. The line from second chlorine trap 598 can go directly to the pump. A suitable pump is, for example, a dry rotary pump from Edwards, such as model QDP80.

For the handling of large substrates, appropriate substrate handling approaches can be used. With product deposition onto the top of the substrate, a wider range of substrate handling approaches become feasible since the bottom of the substrate can then be contacted without damaging the coating. Thus, a conveyor system can be used to bring in, scan through the coating process one or more time, and remove the substrate from the coating area. A roller based system can be convenient since the rollers can be selected to be tolerant of temperatures used to heat the substrate. One or more of the rollers can be motorized to propel the substrate. The roller based conveyor system can interface with additional conveyor components as the substrates are moved away from the coating area. Other suitable conveyor systems include, for example, air-driven, contact-less conveyors with stainless steel surfaces.

One embodiment of a conveyor system is shown in FIG. 18. A large area substrate 480 is carried on rollers 482. Substrate 480 can be made from Silicon Carbide or other suitable material that is tolerant of the appropriate temperature range. Rollers 482 can be formed from quartz or other suitable material. As shown in the figure, 7 silicon carbide resistive heater rods 484 are positioned to heat portions of the substrate prior to and during the coating process. Reactant inlet nozzle 486 is positioned to direct a reactant flow to a light reaction zone 488 so that a product stream is directed onto substrate 480. A light beam is positioned to propagate perpendicular to the plane of the figure. Nozzle 486 is elongated in the direction perpendicular to the page so that the entire width of substrate 480 is coated in one pass.

The temperature of the substrate during the deposition process can be adjusted to achieve particular objectives. For example, the substrate can be cooled during the deposition process since a relatively cool substrate can condense the product composition on its surface. However, in some embodiments, the substrate is heated during the deposition process to promote softening of the coating materials. Suitable heating temperatures can depend on the particular coating materials.

The composition of the coating material can be changed incrementally or discretely to produce layers with varying composition, which can involve a gradual change in composition between two compositions or discrete layers with discrete composition differences. The resulting transition material can have a step-wise change in composition from a first composition to a second composition. Generally, the first composition and second composition are the compositions of the adjacent layers (or adjacent compositions in the same layer) such that the transition material provides a gradual transition in composition between the two adjacent layers. While a transition material can have two layers, the transition material generally has at least three layers, in other embodiments at least 4 layers and in further embodiments in the range(s) from 5 layers to 100 layers. A person of ordinary skill in the art will recognize that additional range(s) within these specific ranges are contemplated and are within the present disclosure. The total thickness can be selected as desired. For some embodiments of interest, each layer within the step-wise transition material generally has a thickness less than about 100 microns, in other embodiments less than about 25 microns, in further embodiments in the range(s) from about 500 nm to about 20 microns and in additional embodiments in the range(s) from about 1 micron to about 10 microns. A person of ordinary skill in the art will recognize that additional ranges within the specific ranges of layer numbers and layer thickness are contemplated and are within the present disclosure. The layers within the step-wise transition material may or may not have approximately equal thickness. Similarly, the step-wise change in composition may or may not take equivalent steps between layers of the transition material.

For the production of discrete devices or other patterned structures on a substrate surface, the composition of the material generally is different at different locations within the structure. To introduce the composition variation, the deposition process itself can be manipulated to produce specific structures. Alternatively, various patterning approaches can be used following the deposition for the formation of selected structures.

Using the deposition approaches described herein, the composition of product deposited on the substrate can be changed during the deposition process to deposit coating material with a particular composition at selected locations on the substrate to vary the resulting composition of the coating material along the x-y plane. For example, if the product compositions are changed while sweeping the substrate through the product stream, stripes or grids can be formed on the substrate surface with different coating compositions in different stripes or grid locations. Using light reactive deposition, the product composition can be varied by adjusting the reactants that react to form the product compositions or by varying the reaction conditions. In some embodiments, the reactant flow can comprise vapor and/or aerosol reactants, which can be varied to alter the composition of the products. Similarly, dopant concentrations can be selected by varying the composition and/or quantity of dopant elements in the flow. The reaction conditions can also affect the resulting product properties. For example, the reaction chamber pressure, flow rates, radiation intensity, radiation energy/wavelength, concentration of inert diluent gas in the reaction stream, temperature of the reactant flow can affect the composition and other properties of the product materials.

While product composition changes can be introduced by changing the reactant flow composition or the reaction conditions while sweeping a substrate through the product stream, it may be desirable, especially when more significant compositional changes are imposed, to stop the deposition between the different deposition steps involving the different compositions. For example, to coat one portion of a substrate with a first composition and the remaining portions with another composition, the substrate can be swept through the product stream to deposit the first composition to a specified point at which the deposition is terminated. The substrate is then translated the remaining distance without any coating being performed. The composition of the product is then changed, by changing the reactant flow or reaction conditions, and the substrate is swept, after a short period of time for the product flow to stabilize, in the opposite direction to coat the second composition in a complementary pattern to the first composition.

The deposition process can be generalized for the deposition of more than two compositions and/or more elaborate patterns on the substrate. In the more elaborate processes, a shutter can be used to block deposition while the product flow is stabilized and/or while the substrate is being positioned. A precision controlled stage/conveyor can precisely position and sweep the substrate for the deposition of a particular composition. The shutter can be rapidly opened and closed to control the deposition. Gaps may or may not be used to space the different location of the compositions within the pattern. If present, the small gap can filled in during a subsequent heating step to form a smooth surface with a relatively sharp boundary between the two materials. Alternatively or additionally, voids can be left in the coating such that troughs or voids can be integrally a part of the layer structure, if desired. The capability of directly forming a dense high quality coating with selected voids would be a unique feature of the light reactive dense deposition.

In some embodiments, a discrete mask can be used to control the deposition of product composition. With chemical vapor deposition and physical vapor deposition, a layer of material is built up from an atomic or molecular level, which can involve intimate binding of the mask to the underlying substrate at an atomic or molecular level to prevent migration of the material being deposited under the mask to blocked regions. Thus, the coated masks are a coating on the surface without an independent, self-supporting structure corresponding to the mask, and the coated mask is chemically or physically bonded to the surface with atomic level contact along the coated mask. In contrast, with product deposition as described herein, the product is directly flowed to the substrate surface at a high rate such that a mask with a flat surface placed against another flat surface provides sufficient contact to prevent significant product migration past the mask over the time frame of the deposition process. While coated masks can be effectively used in light reactive deposition, physical masks provide an efficient alternative to coated masks for patterning a surface using light reactive deposition. The physical masks can have an intact self-supporting structure that is not bonded to the surface such that the mask can be removed intact from the surface that is coated. Therefore, the discrete mask approach herein is different from previous masking approaches adapted from photolithography for vapor deposition approaches.

In these embodiments, the formation of the coating correspondingly involves directing a product stream at the substrate shielded with the discrete mask. The discrete mask has a surface, generally a planar surface, with openings at selected locations. The discrete mask blocks the surface except at the openings such that product composition from the flow can deposit on the surface through the openings. Thus, the mask provides for patterning compositions on the surface by the selected placement of the openings. In some embodiments, suitable discrete masks comprise a mask with a slit that is narrower than the product flow such that the deposition process can be very precisely controlled. Movement of the slit can form a desired, precisely controlled pattern with one or more compositions. After use of a discrete mask, it can be removed and reused.

In some embodiments, a plurality of masks can be used to deposit coating material along a single layer. For example, following deposition of a pattern through a first mask, a second complementary mask can be used to deposit material over at least a portion of the surface left uncovered during deposition with the first mask. Further complementary masks can be used to form complex patterns while completing a single layer or portion thereof with a coating having varying chemical composition over the layer. Similarly, non-complimentary masks can be used to form non-planar structures that may or may not be subsequently leveled off. For example, texture can be formed as non-planar elements formed with one or more masks. The textured structure can be incorporated into the structure for convenient use in the ultimate product, such as a solar cell. Selected voids can be left as desired following the use of the plurality of physical masks.

Thus, using light reactive deposition, a range of effective approaches are available to vary the chemical composition of coating materials within layers and in different layers to form three-dimensional structures with selected compositions are selected locations within the material. In other words, the properties, such as optical, electromagnetic and/or physical properties, and/or chemical composition of the coating materials can be varied along all three axes, x, y and z, within the three-dimensional structure to form the desired assembly. The patterning of compositions of materials, particularly optical materials, during a light reactive deposition process is described further in copending and commonly assigned U.S. patent application Ser. No. 10/027,906 to Bi et al., entitled “Three Dimensional Engineering of Optical Structures,” incorporated herein by reference, and these approaches can be further adapted for light reactive deposition using the teachings herein.

The substrate selected for the deposition process can be selected to tolerate the temperatures of the deposition as well as having appropriate surface properties, such as smoothness and/or texturing. Some substrates become a permanent portion of an ultimate device and may be selected for its functional properties. For example, a transparent substrate can be used to form the front surface of a photovoltaic cell or a display. In additional or alternative embodiments, the substrate is a temporary part of the structure that is separated at a later stage through a release layer. Suitable transparent substrates can comprise, for example, ceramic glasses, such as silica glasses. Other suitable substrates include, for example, metal substrates, ceramic substrates and the like. The surface of the substrate can be textured, for example, with periodic undulations, periodic bumps, random or pseudo-random texturing with selected degree of surface texture or the like.

### Composition of Coatings

The performance of light reactive deposition can be used to produce coatings with a selected composition from a broad range of available compositions. Specifically, the compositions can comprise one or more metal/metalloid elements forming a crystalline or amorphous material with an optional dopant composition. In addition, dopant(s) can be used to alter the chemical and/or physical properties of the coating. Incorporation of the dopant(s) into the reactant flow can result in a distribution of the dopant(s) through the coating material. In some embodiments, compositions of particular interest comprise silicon/germanium-based semiconductor optionally with a selected dopant.

In general, coating materials can comprise, for example, elemental metal/metalloid, and metal/metalloid compositions, such as, metal/metalloid oxides, metal/metalloid carbides, metal/metalloid nitrides, metal/metalloid phosphides, metal/metalloid sulfides, metal/metalloid tellurides, metal/metalloid selenides, metal/metalloid arsinides, mixtures thereof, alloys thereof and combinations thereof. Alternatively or additionally, such coating compositions can be characterized as having the following formula:

AₐB_{b}C_{c}D_{d}EₑF_{f}G_{g}HₕIᵢJⱼKₖLₗMₘNₙOₒ,

where each A, B, C, D, E, F, G, H, I, J, K, L, M, N, and O is independently present or absent and at least one of A, B, C, D, E, F, G, H, I, J, K, L, M, N, and O is present and is independently selected from the group consisting of elements of the periodic table of elements comprising Group 1A elements, Group 2A elements, Group 3B elements (including the lanthanide family of elements and the actinide family of elements), Group 4B elements, Group 5B elements, Group 6B elements, Group 7B elements, Group 8B elements, Group 1B elements, Group 2B elements, Group 3A elements, Group 4A elements, Group 5A elements, Group 6A elements, and Group 7A elements; and each a, b, c, d, e, f, g, h, i, j, k, l, m, n, and o is independently selected and stoichiometrically feasible from a value in the range(s) from about 1 to about 1,000,000, with numbers of about 1, 10, 100, 1000, 10000, 100000, 1000000, and suitable sums thereof being contemplated. The materials can be crystalline, amorphous or combinations thereof. In other words, the elements can be any element from the periodic table other than the noble gases. As described herein, all inorganic compositions are contemplated, as well as all subsets of inorganic compounds as distinct inventive groupings, such as all inorganic compounds or combinations thereof except for any particular composition, group of compositions, genus, subgenus, alone or together and the like.

For some applications of particular interest herein, the full capabilities of light reactive deposition with respect to ranges of compositions generally may not be needed. However, if a plurality of device components is formed using light reactive deposition, it may be desirable to form coatings with a range of coating compositions. As noted above, a significant focus of the description herein relates to the formation of large area silicon/germanium-based semiconductor materials. Elemental silicon can be formed using a silane precursor (SiH₄), which absorbs infrared light from a CO₂ laser to decompose into elemental silicon. No other reactants are needed in the flow, although other reactants or light absorbers can be included and an inert gas can be used as a diluent. Elemental germanium can be similarly formed with germanium precursors, such as GeH₄, substituted for the silicon precursors, and alloys can be formed with partial substitution of germanium precursors for silicon precursors.

In some embodiments, it is desirable to incorporate one or more dopants into the silicon/germanium-based semiconductor, for example, to form n-type semiconductors or p-type semiconductors. Suitable dopants to form n-type semiconductors contribute extra electrons, such as phosphorous (P), arsenic (As), antimony (Sb) or mixtures thereof. Similarly, suitable dopants to form p-type semiconductors contribute holes, i.e., electron vacancies, such as boron (B), aluminum (Al), gallium (Ga), indium (In) or combinations thereof.

Suitable precursors for Si include, for example, silane (SiH₄), monochlorosilane (ClSiH₃), dichlorosilane (C₁₂H₂Si), trichlorosilane (Cl₃HSi) and disilane (Si₂H₆) for gas/vapor delivery and silicon tetrachloride (SiCl₄) for aerosol delivery. Suitable Ge precursors include, for example, germane (GeH₄) and GeCl₄ for vapor delivery. Suitable boron precursors include, for example, BCl₃, BH₃, B₂H₆ and the like for vapor delivery and (NH₄)₂B₄O₇ for aerosol delivery. Suitable P precursors include, for example, phosphine (PH₃), phosphorous trichloride (PCl₃), phosphorous pentachloride (PCl₅) phosphorous oxychloride (POCl₃) for vapor delivery and phosphoric acid (H₃PO₄) for aerosol for aerosol delivery. Suitable Al precursors include, for example, AlH₃, Al₂H₆, aluminum chloride (AlCl₃) and the like for vapor delivery and aluminum hydroxychloride (Al₂(OH)₅Cl.H₂O) for aerosol delivery. Suitable Sb precursors include, for example, SbH₃ for vapor delivery and SbCl₃ for aerosol delivery. Suitable precursors for vapor delivery of gallium include, for example, GaH₃, and suitable precursors for aerosol delivery of gallium include, for example, gallium nitrate (Ga(NO₃)₃). Arsenic precursors include, for example, AsH₃ and AsCl₃, which are suitable for vapor delivery, and AS₂O₅, which is suitable for aerosol precursor delivery in aqueous or alcohol solutions. Suitable precursors for the aerosol delivery of indium include, for example, indium sulfate and indium trichloride.

Dopant concentrations can be selected to yield desired properties. In some embodiments, the average dopant concentrations can be at least about 1×10¹³ atoms per cubic centimeter (cm³), in further embodiments, at least about 1×10¹⁴ atoms/cm³, in other embodiments at least about 1×10¹⁶ atoms/cm³ and in further embodiments 1×10¹⁷ to about 5×10²¹ atoms/cm³. With respect to atomic parts per million (ppma), the dopant can be at least about 0.0001 ppma, in further embodiments at least about 0.01 ppma, in additional embodiments at least about 0.1 ppma and in other embodiments from about 2 ppma to about 1×10⁵ ppma. A person of ordinary skill in the art will recognize that additional ranges of dopant concentrations within the explicit ranges above are contemplated and are within the present disclosure. While certain people of ordinary skill in the art use n+, n++, p+ and p++ to designate certain dopant concentration ranges for n-type and p-type dopants, this notation is not used herein to avoid possible ambiguities or inconsistencies.

In general, the dopant concentrations may or may not be uniformly distributed through a layer of material. In some embodiments, there is a gradient in dopant concentration. A gradient can be step-wise. Such a gradient can be selected to yield desirable efficiencies in the resulting product. Specifically, gradients near surfaces and interfaces can be useful for reducing electrical loses at surfaces and interfaces.

Suitable dielectric materials for appropriate applications include, for example, silicon/germanium/metal oxides, silicon/germanium/metal carbides, silicon/germanium/metal nitrides, combinations thereof, or mixtures thereof. If the dielectric is adjacent a semiconductor layer comprising silicon and/or germanium, it can be convenient to use a corresponding silicon/germanium composition for the dielectric. Thus, for a silicon-based photovoltaic, it may be desirable to incorporate a silicon oxide, a silicon nitride, a silicon oxynitride and/or a silicon carbide as a dielectric adjacent the silicon-based semiconductor.

Suitable conductive electrodes can be deposited as a layer or a pattern within an overall structure. In particular, metals, such as Al, Cu, Ag, Au, Ni and the like, can be deposited as a conductive material. Aluminum (Al) can be conveniently deposited adjacent a p-type semiconductor since any aluminum that migrates into the semiconductor layer contributes as a p-type dopant to form a better contact. Suitable materials for transparent/translucent electrodes include, for example, tin oxide and indium tin oxide.

Suitable materials for a release layer can be selected based on the properties of the adjacent materials. In particular, in some embodiments, the release layer is formed from a material with a higher melting point or glass transition temperature than the flow temperature of the adjacent materials. In general, based on the wide range of materials available with light reactive deposition, a person of ordinary skill in the art can select a suitable material for the release layer. With respect to a release layer of an elemental silicon layer, it is desirable to select a layer that not only tolerates the melting temperature of silicon but also wets molten silicon so that the silicon is less likely to bead when melted since molten silicon has a relatively large surface tension. Suitable materials for a release layer for silicon include, for example, silicon nitride (Si₃N₄) or silicon rich silicon oxide (SiOₓ, x<2).

For material synthesis in a reactive flow, suitable oxygen sources include, for example, O₂, N₂O or combinations thereof, and suitable nitrogen sources include, for example, ammonia (NH₃), N₂ and combinations thereof. The range of compositions available with light reactive deposition is described further in copending U.S. patent application Ser. No. 11/017,214 to Chiruvolu et al., entitled “Dense Coating Formation by Reactive Deposition,” incorporated herein by reference.

### Coating Properties

Light reactive deposition is a versatile approach for the high rate formation of high quality coatings. The coating properties can be considered as deposited and/or after post-deposition processing. If multiple layers are deposited using light reactive deposition, there may or may not be additional processing between the deposition of a subsequent layers. The porosity of a layer can depend in part on the density of a particular layer. If the coating is deposited with a relatively large density, the coating generally has mechanical stability, while some layers intended as release layers can be purposefully deposited to have relatively small mechanical stability. The coatings can be formed with smooth surfaces and a high degree of uniformity both across a particular coating as well as between coatings on different substrates performed under equivalent conditions. These properties provide for the formation of useful large surface area structures as well as multiple layers of large area structures. While the coatings can be smooth, texture with controlled properties can correspondingly be designed into the coating.

The relative density of a coating is evaluated relative to the fully densified material of the same composition. For coatings deposited with lower densities, the coating can have a relative density of no more than about 0.65, in further embodiments from about 0.10 to about 0.6, and in other embodiments from about 0.2 to about 0.5. In general, the a dense coating can have a relative density in the range(s) of at least about 0.65, in other embodiments in the range(s) from about 0.7 to about 0.99, in some embodiments from about 0.75 to about 0.98 and in further embodiments in the range(s) from about 0.80 to about 0.95. A person of ordinary skill in the art will recognize that additional ranges within these specific ranges of coating density are contemplated and are within the present disclosure. Light reactive deposition can form a dense coating with approximately the same density as the fully densified material. Regardless of the density of the initial as-deposited coating, during post processing the density can be increased as desired to a selected value from the initial density to the full density. The density of the dense coating can be evaluated by weighting the substrate before and after coating and dividing the weight by the volume of the coating. Coating thickness can be evaluated using scanning electron microscopy. A decrease in density may or may not be associated with a measurable porosity of the surface. Porosity can also be evaluated using scanning electron microscopy (SEM).

To obtain particular objectives, the features of a coating can be varied with respect to composition of layers of the coating as well as location of materials on the substrate. Generally, to form a device the coating material can be localized to a particular location on the substrate. In addition, multiple layers of coating material can be deposited in a controlled fashion to form layers with different compositions. Similarly, the coating can be made a uniform thickness, or different portions of the substrate can be coated with different thicknesses of coating material. Different coating thicknesses can be applied such as by varying the sweep speed of the substrate relative to the particle nozzle, by making multiple sweeps of portions of the substrate that receive a thicker coating or by patterning the layer, for example, with a mask. Approaches for the selective deposition of coating material are described above. Alternatively or additionally, a layer can be contoured by etching or the like following deposition.

Thus, layers of materials, as described herein, may comprise particular layers that do not have the same planar extent as other layers. For example, some layers may cover the entire substrate surface or a large fraction thereof while other layers cover a smaller fraction of the substrate surface. In this way, the layers can form one or more localized devices. At any particular point along the planar substrate, a sectional view through the structures may reveal a different number of identifiable layers than at another point along the surface.

Light reactive deposition can be used to form thick coatings. However, the approach has advantages for forming high quality coatings for applications in which an appropriate coating thickness is generally moderate or small, and very thin coatings can be formed as appropriate. Thickness is measured perpendicular to the projection plane in which the structure has a maximum surface area. For some applications, the coatings have a thickness in the range(s) of no more than about 2000 microns, in other embodiments, in the range(s) of no more than about 500 microns, in additional embodiments in the range(s) from about 5 nanometers to about 100 microns and in further embodiments in the range(s) from about 100 nanometers to about 50 microns. A person of ordinary skill in the art will recognize that additional range(s) within these explicit ranges and subranges are contemplated and are encompassed within the present disclosure.

The approaches described herein provide for the formation of coating layers that have very high uniformity within a layer and between layers formed under equivalent conditions. Thicknesses of a coating layer can be measured, for example, with an SEM analysis can be performed on a cross section, for example, at about 10 points along a first direction and about 10 points across the perpendicular direction. The average and standard deviation can be obtained from these measurements. In evaluating thickness and thickness uniformity of a coating layer, a one centimeter band along the edge can be excluded.

In some embodiments, one standard deviation of the thickness on a substrate with an area of at least about 25 square centimeters can be in the range(s) of less than about 10 microns, in other embodiments less than about 5 microns and in further embodiments from about 0.5 to about 2.5 microns. In addition, the standard deviation of the average thickness between a plurality of substrates coated under equivalent conditions can be less than about 10 microns, in other embodiments less than about 5 microns and in further embodiments from about 0.1 to about 2 microns. A person of ordinary skill in the art will recognize that additional deviations in thickness within a layer and between layers of different substrates within the explicit ranges above are contemplated and are within the present disclosure.

In some embodiments, very low surface roughness for a dense coating, with or without consolidation, on a substrate can be achieved. For embodiments in which surface texturing is desired, the low surface roughness values described below reflect the uniformity of the surface roughness that can be achieved if desired. Surface roughness is evaluated generally with respect to a specific area of the surface for comparison. Different techniques may be particularly suited for the evaluation of surface roughness over particular areas due to time and resolution issues. For example, atomic force microscopy (AFM) can be used to evaluate a root mean square surface roughness over an approximate 20 micron by 20 micron area of a substrate, which is referred to herein as R_{AFM}. A suitable AFM instrument includes, for example, a Digital Instruments (Santa Barbara, Calif.) Model Nanoscope® 4. Using the techniques described herein, R_{AFM} values and similarly average roughness values (Rₐ) can be obtained in the ranges of no more than about 0.5 nanometers (nm), and in other embodiments in the ranges from about 0.1 nm to about 0.3 nm. Interferometry can be used to obtain surface roughness measurements over larger areas, such as 480 microns×736 microns. An interferometric profiler is an optical non-contact technique that can measure surface roughness from sub-nanometer to millimeter scales. A suitable interferometric profiler using digital signal processing to obtain surface profile measurement is a Wyko series profiler from Veeco Instruments Inc. (Woodbury, N.Y.). Using light reactive dense deposition, root mean square surface roughness (Rᵣₘₛ) values and similarly the average surface roughness (Rₐ) over 480 microns×736 microns can be obtained in the ranges of no more than about 10 nm and in further embodiments from about 1 nm to about 5 nm. A person of ordinary skill in the art will recognize that additional ranges of surface roughness within the explicit ranges are contemplated and are within the present disclosure.

The texturing can be characterized with a peak-to-peak distance. The average peak-to-peak distance can be from about 100 nm to 10 microns, in further embodiments from about 250 nm to about 7.5 microns and in further embodiments from about 500 nm to about 5 microns. In some embodiments, the average slope of a peak can range from about 30 to about 60 degrees and in further embodiments from about 40 to about 50 degrees. These parameters can be determined from an examination of the surface with scanning electron microscopy. A person of ordinary skill in the art will recognize that additional ranges of texture parameters within the explicit ranges above are contemplated and are within the present disclosure.

Due to the very high deposition rate combined with the high coating uniformity with light reactive deposition, large substrates can be effectively coated. With larger widths of the substrate, the substrate can be coated with one or multiple passes of the substrate through the product stream. Specifically, a single pass can be used if the substrate is roughly no wider than the inlet nozzle of the reactor such that the product stream is approximately as wide or wider than the substrate. With multiple passes, the substrate is moved relative to the nozzle in a direction oriented along the width of the substrate. Thus, it is straightforward to coat substrates in some embodiments with a width of at least about 20 centimeters, in other embodiments at least about 25 cm, in additional embodiments from about 30 cm to about 2 meters, in further embodiments no more than about 1.5 meters and in some embodiments no more than 1 meters. A person of ordinary skill in the art will recognize that additional ranges of widths within these explicit ranges are contemplated and are within the present disclosure.

In general, for convenience, the length is distinguished from the width of a substrate in that during the coating process, the substrate is generally moved relative to its length and not relative to its width. With this general principle in mind, the distinction may or may not be particularly relevant for a particular substrate. The length is generally only limited by the ability to support the substrate for coating. Thus, lengths can be at least as large as about 10 meters, in some embodiments from about 10 cm to about 5 meters, in further embodiments from about 30 cm to about 4 meters and in additional embodiments from about 40 nm to about 2 meters. A person of ordinary skill in the art will recognize that additional ranges of substrate lengths within these explicit ranges are contemplated and are within the present disclosure.

As a result of being able to coat substrates with large widths and lengths, the coated substrates can have very large surface areas. In particular, substrates sheets can have surface areas of at least about 900 square centimeters (cm²), in further embodiments, at least about 1000 cm², in additional embodiments from about 1000 cm² to about 2 square meters (m²) and in other embodiments from about 2500 cm² to about 5 m². With the ability to form thin structures through the use of a release layer, the large surface areas can be combined with particularly thin structures. In some embodiments, the large surface area structures can have a thickness of no more than about a millimeter, in other embodiments no more than about 250 microns, in additional embodiments no more than about 100 microns and in further embodiments from about 5 microns to about 50 microns. A person of ordinary skill in the art will recognize that additional ranges of surface area and thickness within the explicit ranges above are contemplated and are within the present disclosure. While these thin, large area structures can be formed with a range of materials that can be produced with light reactive deposition, in some embodiments there is particular interest in thin silicon/germanium-based semiconductor materials with or without dopants.

The properties of the sheet as a semiconducting material can be described in terms of minority carrier diffusion length and carrier mobility. For photovoltaic applications, the presence of a larger minority carrier diffusion length correlates with a slower recombination rate and a corresponding higher efficiency of the photovoltaic cell. Thus, it is desirable to have a minority carrier diffusion length for the silicon/germanium-based semiconductor sheet of at least about 30 microns and in further embodiments at least about 70 microns. A person of ordinary skill in the art will recognize that additional ranges of minority carrier diffusion length are contemplated and are within the present disclosure. An increased minority carrier diffusion length can be obtained by improving the crystallinity of the material and obtaining a larger average crystallite size.

The minority carrier diffusion length can be correlated with carrier lifetime values. Minority carrier lifetimes can be measured with a charge coupled camera operating in the infrared portions of the spectrum that is used to measure infrared transmission of the sample. High resolution scans of the material can be obtained quickly. An article by Isenberg et al. describes the use of an infrared laser and a commercial CCD camera to obtain a resolution down to 30 microns across the surface of the semiconductor material. The citation for the Isenberg article is Journal of Applied Physics, 93(7):4268-4275 (1 Apr. 2003), entitled “Imaging method for laterally resolved measurement of minority carrier densities and lifetimes: Measurement principle and first applications,” incorporated herein by reference. An article by Goldschmidt et al. discusses the calculation of short-circuit current and open-circuit voltage based on measurements of carrier lifetimes. The Goldschmidt article was presented at the 20th European Photovoltaic Solar Energy Conference and Exhibition, 6-10 June 2005, Barcelona, Spain, entitled “Predicting Multi-Crystalline Silicon Solar Cell Parameters From Carrier Density Images,” incorporated herein by reference. An alternative approach for contact-less estimation of charge-current performance of silicon material is described in Trupke et al., Applied Physics Letters 87:093503 (2005), entitled “Suns-photoluminescence: Contactless determination of current-voltage characteristics of silicon wafers,” incorporated herein by reference. The processes in the Trupke article can be generalized for spatial resolution across the semiconductor surface.

Carrier mobility is a significant parameter for semiconductor performance in electronics applications. For the semiconductor sheets described herein, the electron mobilities can be at least about 5 cm²/Vs, in further embodiments at least about 10 cm²/Vs and in other embodiments at least about 20 cm² Vs. A person of ordinary skill in the art will recognize that additional ranges of carrier mobility within the ranges above are contemplated and are within the present disclosure. Evaluation of carrier mobility for semiconductor samples is described, for example, in U.S. Pat. No. 5,966,019 to Borden, entitled “System and Method for Measuring Properties of a Semiconductor Substrate in a Fabrication Line,” incorporated herein by reference.

### Incorporation of Dopant into a Semiconductor Layer

While the compositions can be selected during deposition by appropriately introducing precursors into the reactant stream for particle production, alternatively or additionally, a composition, such as silicon/germanium-based semiconductor, can be modified across the entire coating or selected portion thereof following formation of the layer. Portions of the layer can refer to portions along the expanse of the coating surface and/or portions of the layer thickness. The modification of the composition generally can be performed with either powder coatings or denser coatings.

Generally, one or more modifying elements can be applied to the layer as a composition comprising the desired element. The semiconductor material can be heated near or at its melting temperature to incorporate the element into the semiconductor materials. Patterning approaches can be used to incorporate the elements, such as dopants, into a portion of the layer.

The modifying element, e.g., a dopant(s)/additive(s), can be introduced into a selected portion of the layer by selectively contacting the composition with only a portion of the layer using solution barriers or the like. Alternatively or additionally, a portion of the layer can be covered with a mask, such as conventional resist used in electronic processing, to block migration of the modifying element into the masked regions. Referring to an embodiment in FIG. 19, layer 600 can be in contact with mask 602 confining contact of a modifying composition with the layer to an area uncovered by the mask. Then, the coating is doped in un-masked portions. Masking generally is selected to form desired structures within the layer. Multiple modifying elements can be sequentially applied to the same and/or different portions of a layer by altering the masking between deposition step of the different modifying elements. The modifying compositions or elements thereof can be incorporated into the material through heat treatment and/or laser drive-in.

In addition to photolithographic and other masking techniques, moderate resolution can be achieved using conventional printing approaches with the added compositions being added as inks, which optionally can be used along with a masking approach. For example, ink jet printing can be successfully used to deposit functional inks at desired locations in which the functional inks deliver the selected composition to modify the coating composition. Similarly, other printing approaches can be used, such as off-set printing, gravure printing and the like. The use of doped silica particles dispersed in a liquid as a printable ink to supply dopants to a semiconductor material is described further in copending provisional application Ser. No. 60/878,239 to Hieslmair et al., entitled “Doped Dispersions and Processes for Doping Semiconductor Substrates,” incorporated herein by reference.

As noted above, the modifying composition can be incorporated into an initially dense material through a heating process in which the coating is heated near or above its melting or flow temperature so that the element can migrate into the composition. In additional or alternative embodiments, a dopant can be incorporated into a shallow zone of the coating through a laser drive in. For example, a high power laser can be pulsed to melt a localized region of the coating near its surface. The dopant or other modifying element/composition then diffuses into the melted zone. The use of laser drive in to form shallow doped domains as portions of photovoltaic contacts is described further in copending provisional patent application Ser. No. 60/902,006 to Hieslmair et al., filed on Feb. 16, 2007, entitled “Photovoltaic Cell Structures, Solar Panels and Corresponding Processes,” incorporated herein by reference.

In general, the various approaches for introducing a modifying element into a layer can be combined for the introduction of one or more modifying elements into a layer. For example, a particular modifying element can be introduced using a plurality of techniques to achieve desired levels of modifying element and/or distributions of modifying element within the layer. In addition, for the deposition of a plurality of modifying elements, each modifying element can be deposited using one or more of the techniques described above, for convenience of processing and/or to achieve desired properties of the resulting materials.

### Heat Treatments and Other Post-Deposition Processing of a Coating on a Substrate

Heat treatment can sinter the particles of a powder coating and lead to compaction, i.e., densification, of the powders/powder coatings to form the desired material density. While dense coatings can be essentially deposited in a form selected for an intended use, some additional processing can be appropriate or desirable. To densify the coating materials, the materials can be heated to a temperature above the melting point for crystalline materials or the flow temperature for amorphous materials, e.g., above the glass transition temperature and possibly above the softening point below which a glass is self-supporting, to consolidate the coating into a densified material by forming a viscous liquid. Sintering of particles can be used to form amorphous, crystalline or polycrystalline phases in layers. A preliminary heat treatment can be applied with the reactor flame to reduce dopant(s)/additive(s) migration during the subsequent heating process and to partly densify the material.

The sintering of crystalline particles can involve, for example, one or more known sintering mechanisms, such as surface diffusion, lattice diffusion, vapor transportation, grain boundary diffusion, and/or liquid phase diffusion. The sintering of amorphous particles generally can lead to the formation of an amorphous film. The coating layers can be completely or partially densified. In general, densification can be performed before or after patterning of a layer. A partially densified material can be a material in which a pore network remains but the pore size has been reduced and the solid matrix strengthened through the fusing of particles to form rigid inter-particle necks.

Furthermore, some processing of the deposited layers can further improve the quality of the coating, for example with respect to crystallinity or purity. Other processing can modify the composition of the material or add additional compositions to the coating. For initially dense coatings, some additional processing can involve the application of heat, although the processing temperatures generally can be significantly less than temperatures used for densification of powder coatings into a dense coating.

For embodiments in which the coating is formed dense, sintering or other major compaction of the coating generally may not be needed. For these embodiments, the dense coating generally is not heated up to a flow temperature, such as a melting point or glass transition temperature. However, the material can be heated to anneal the material to improve the uniformity and/or crystallinity. This heating can result in some compaction of the material, with a corresponding increase in the density. The annealing temperature generally may be no more than about 60 percent of the flow temperature, and in other embodiments no more than about 50 percent of the flow temperature in centigrade units. Such heating can remove some impurities, such as carbon impurities if the heating is performed in an oxidizing atmosphere. Generally, heating a dense coating under these conditions does not alter the structure of the material, i.e., amorphous, polycrystalline or crystalline. Suitable processing temperatures and times generally depend on the composition of the dense coating.

Following deposition of a layer with light reactive deposition, the precursors can be shut off such that the reactant stream only comprises, a fuel and an oxygen source that reacts to form gaseous/vapor products without condensable materials. The flame resulting from the reaction of the fuel and oxygen source can be used to heat the coated substrate without depositing any additional materials on the substrate. Such a heating step has been observed to reduce dopant(s)/additive(s) migration upon full consolidation of a doped silica glass. A flame heating step can be performed between coating steps or after deposition of several layer, in which each coating layer may or may not have the same composition as other layers. Following an in situ flame heating step, one or more additional heating steps can also be performed after removing the substrate from the reactor.

Heat treatments for coated substrates can be performed in a suitable oven. It may be desirable to control the atmosphere in the oven with respect to pressure and/or the composition of the surrounding gases. Suitable ovens can comprise, for example, an induction furnace, a box furnace or a tube furnace with gas(es) flowing through the space containing the coated substrate. The heat treatment can be performed following removal of the coated substrates from the coating reactor. In alternative embodiments, the heat treatment is integrated into the coating process such that the processing steps can be performed sequentially in the apparatus in an automated fashion. Suitable processing temperatures and times generally depend on the composition and microstructure of the coatings. For powder coatings, small particles on the submicron/nanometer scale generally can be processed at lower temperatures and/or for shorter times relative to powders with larger particles due to lower melting/softening points, higher atomic mobility, and higher vapor pressure for the submicron/nanoscale particles in comparison with bulk material.

For many applications, it is desirable to apply multiple coatings with different compositions and/or morphology. In general, these multiple coatings can be arranged adjacent to each other across the x-y plane of the substrate being coated (e.g., perpendicular to the direction of motion of the substrate relative to the product stream), or stacked one on top of the other across the z plane of the substrate being coated, or in any suitable combination of adjacent domains and stacked layers. Each coating can be applied to a desired thickness.

For some embodiments, different compositions can be deposited adjacent to each other within a layer and/or in adjacent layers. Similarly, distinct layers of different compositions can be deposited in alternating layers. Specifically, two layers with different compositions can be deposited with one on top of the other, and or additionally or alternatively, with one next to the other, such as layer A and layer B formed as AB. In other embodiments, more than two layers each with different compositions can be deposited, such as layer A, layer B and layer C deposited as three sequential (e.g., stacked one on top of the other, or adjacent to the other, or adjacent and stacked) layers ABC. Similarly, alternating sequences of layers with different compositions can be formed, such as ABABAB . . . or ABCABCABC . . . Other combinations of layers with specific compositions and/or optical properties can be formed as desired.

Individual densified layers, each of a particular composition, generally have after consolidation an average thickness in the range(s) of no more than 3000 microns, in further embodiments in the range(s) of no more than about 1000 microns, in additional embodiments, in the range(s) of no more than about 250 microns, in some embodiments in the range(s) from about 0.1 micron to about 50 microns, in other embodiments in the range(s) from about 0.2 microns to about 20 microns. A person of skill in the art will recognize that ranges within these specific ranges are contemplated and are within the scope of the present disclosure. Each uniform layer formed from particles with the same composition can be formed from one or more passes through a product flow in a light reactive deposition apparatus. Thickness is measured perpendicular to the projection plane in which the structure has a maximum surface area.

The material with multiple particle coatings can be heat treated after the deposition of each layer or following the deposition of multiple layers or some combination of the two approaches. A suitable processing order generally depends on the densification mechanisms of the material. However, it may be desirable to heat treat a plurality of layers simultaneously. Specifically, heat-treating multiple layers simultaneously can reduce the time and complexity of the manufacturing process and, thus, reduce manufacturing costs. If the heating temperatures are picked at reasonable values, the heated materials remain sufficiently viscous such that the layers or boundaries within a layer do not merge undesirable amounts at the interface. To form patterned structures following deposition, patterning approaches, such as lithography and photolithography, along with etching, such as chemical etching, dry etching or radiation-based etching, can be used to form desired patterns in one or more layers. This patterning generally is performed on a structure prior to deposition of additional material.

By changing reaction conditions, such as precursor flow or total gas flow, particles can be deposited with changing particle size in the z-direction within a single layer or between layers. Thus, smaller particles can be deposited on top of larger particles and vice versa. This can be useful for the formation of a release layer. In particular, with a gradient in particle size, a heat treatment step can densify the smaller particles to a greater extent than the larger particles such that the less densified portion of the layer with larger particles can form the release layer.

For silicon sandwiched between layers of silicon oxide, the crystallinity of the silicon has been established through a process called zone melt recrystallization (ZMR). In ZMR, a heat source is used that can melt a thin line of silicon film. This heat source is swept across the film. For example, a focused halogen lamp can be used as the linear heat source. A heater can be placed below the structure to control the base temperature of the structure. The speed of movement of the heater is controlled to adjust the distance between the melting front and the solidification front. There is a balance between a faster sweep speed that reduced processing costs with a slower sweep speed to get larger crystal grains and fewer crystal defects.

### Release Layer Properties and Releasing an Overcoat Structure

A release layer has a property and/or composition that distinguish the release layer from adjacent materials. Generally, the property of the release layer provides for the separation of the release layer from one or both of its adjoining materials. Suitable physical properties of a release layer can be, for example, low density, high melting/softening point, low mechanical strength, large coefficient of thermal expansion or combinations thereof. Suitable chemical properties include, for example, solubility in a selected solvent. In addition, the material of the release layer generally should be inert with respect to the other materials at conditions of relevant processing steps, such as at high temperature, in some embodiments. The selected properties of the release layer can be exploited to separate an overlayer(s) from the underlying substrate. In particular, a chemical and/or physical interaction can be applied to the release layer to remove or fracture the release layer.

In general, the thickness of the release layer can span within appropriate thickness ranges described for other layers deposited by light reactive deposition. On one hand, since the release layer may not be used functionally once the overcoat is released, it may be desirable to keep the release layer thin to consume fewer resources. However, if the layer is too thin, certain properties such as mechanical strength may be a function of the thickness such that the release function may be compromised. In general, a person of ordinary skill in the art can adjust the thickness to obtain desired properties of the release layer.

A layered structure with a release layer is shown schematically in FIG. 19. Layered structure 610 comprises a substrate 612, release layer 614 and overcoat layer 616. Substrate 612 can comprise a high quality material that is reused following cleaning with respect to release layer material. Substrate 612 may or may not comprise layers deposited using light reactive deposition. Release layer 614 can comprise one or more materials with properties as described herein. Overcoat layer 616 can comprise one or more materials in one or more layers. The arrow in FIG. 19 schematically depicts the separation of overcoat layer 616 from layered structure 610. Overcoat layer 616 can be further processed before and/or after separation from structure 610 for the formation of a desired product.

For the mechanical fracturing of the release layer, while the low mechanical strength of the release layer material can facilitate fracture of the release layer, generally it is desirable for the release layer to have a lower density than the surrounding materials. In particular, the release layer can have a porosity of at least about 40 percent, in some embodiments at least about 45 percent and in further embodiments from about 50 to about 90 percent porosity. A person of ordinary skill in the art will recognize that additional ranges of porosity within the explicit ranges above are contemplated and are within the present disclosure. Porosity is evaluated from a SEM micrograph of a cross section of the structure in which the area of the pores is divided by the total area.

To achieve a lower density of the release layer, the release layer can be deposited with a lower density than surrounding materials. However, in some embodiments, the lower density of the release layer can result from reduced or eliminated densification of the release layer while the overcoat layer and, optionally, an under-layer are more fully densified. This difference in densification can be the result of having a material with a higher flow temperature than surrounding undensified material and/or a larger primary particle size that results in a higher flow temperature. For these embodiments, the densification of the overcoat layer and, optionally, of an under-layer results in a release layer with a lower density than the surrounding materials and a correspondingly low mechanical strength. This lower mechanical strength can be exploited to fracture the release layer without damaging the overcoat layer.

The separation force can be applied by supplying mechanical energy. Mechanical energy can be supplied, for example, as ultrasonic vibrations, mechanical vibrations shear force and the like. Alternatively, the layers can be pulled apart. In addition, heat/cooling and/or pressure can be supplied to facilitate the separation based on difference in the coefficient of thermal expansion. Cooling can be accomplished, for example, by contacting the structure with liquid nitrogen.

In some embodiments, the release layer can be chemically separated from surrounding layers. For example, the release layer can be soluble in a solvent that does not dissolve the overcoat layer. To etch SiO₂ without reacting with silicon, hydrofluoric acid can be used.

To facilitate the separation of the overcoat from the release layer and substrate, the overcoat material can be releasably adhered to a transfer surface. The transfer surface can be approximately equal in size, larger than or smaller than the surface of the overcoat to be released. The association with a transfer surface can be made, for example, with an adhesive or the like. In some embodiment, static electricity may be sufficient to associate the transfer surface and the overcoat. The transfer surface can be used to apply shear and/or pulling motion to the overcoat to deliver mechanical energy to rupture the release layer. In some embodiments, an overcoat structure can be associated with a transfer surface to facilitate certain processing of the thin separated structure. The adhesive can be chemically or physically removed to release the thin separated structure from the transfer surface associated with a temporary substrate. In some embodiments, the transfer surface can be associated with a permanent substrate that is attached to the overcoat for formation into a product. Also, the thin structure can be transferred between substrates using comparable approaches after release from the release layer. Adhesives and the like can be released with forces and/or with suitable solvents and the like.

If desired, remnants of the release layer can be removed from the release thin structure using etching or polishing. Depending on the nature of the release layer material, residual release layer material can be removed with mechanical polishing and/or chemical-mechanical polishing. Mechanical polishing can be performed with motorized polishing equipment, such as equipment known in the semiconductor art. Similarly, any suitable etching approach, such as chemical etching and/or radiation etching, can be used to remove the residual release layer material.

### Properties and Further Processing of Free Standing Structures

Following release of the overcoat from the substrate through the removal or fracture of the release layer, the overcoat becomes a free standing structure. This free standing structure generally is very thin while it can have a large surface area. The structure may or may not have a patterned structure along its upper surface and may or may not be textured along either its upper surface, lower surface or both. Either or both surfaces of the structure can be further processed toward the formation one or more devices. As noted above, the structure can be temporarily or permanently associated with another substrate to facilitate processing or for the formation of a device. Suitable dimensions are discussed above in the context of the processing approaches.

In general, the overcoat layer, for example a semiconductor sheet, can have a plurality of layers that can be effectively used for the formation of devices. Referring to FIG. 20, free-standing structure 620 comprises two layers 622, 624. Of course, the compositions of the two layers as well as the relative thicknesses can be selected as desired. Similarly, the number of layers can be only one, two, three or more than three. For photovoltaic cell applications, it can be desirable to have one or more thin protective layers and one or more semiconductor layers, which may or may not be doped along the entire layer or a selected portion thereof. Referring to the cross sectional view in FIG. 21, structure 630 has a protective layer 632, a p-doped silicon layer 634 and an n-doped silicon layer 636. In a similar structure, layer 634 is a semiconductor layer and top layer 636 is also a protective layer. For photovoltaic applications, a top and bottom passivation layer functions to provide an electrically insulating layer as well as protection from mechanical and chemical damage.

More complex structures can be used also with different layers having different degrees of doping and/or an un-doped layer. For example, referring to FIG. 22, structure 640 has a protective layer 642, a p-doped silicon layer 644, an un-doped silicon layer 646 and an n-doped silicon layer 648. In general, the structure can be designed to yield desired performance for the final product, and the processing approaches herein provide considerable flexibility for designing the structure.

For the formation of photovoltaic panels, a plurality of cells is generally connected with appropriate electrical connections between the cells. To form a panel, large area free standing structures described herein can be cut to form a plurality of elements with very similar properties that can be matched within a panel. Also, an alternative available using the processes described herein involves the formation of a larger area protective layer with semiconductor islands appropriately placed on the surface of the protective layer, which is subsequently removed to make the surface available to a transparent electrically conductive electrode. To complete the panel, appropriate electrical interconnects can be connected to the islands and other additional processing can be performed to complete the individual cells.

An embodiment of a structure with separate island structures is shown in FIG. 23, which can be formed through deposition patterning or through cutting of a structure. Referring to FIG. 23, structure 660 has a large layer 662 with four islands 664, 666, 668, 670. While shown with four islands, the large layer can have fewer than four islands, such as one, two or three islands, or more than four islands, such as up to a thousand islands. A person or ordinary skill in the art will recognize that additional ranges of island numbers within these explicit ranges are contemplated and are within the present disclosure. Also, large layer 662 and islands 664, 666, 668, 670 can each individually have a plurality of layers. The size, thickness, composition and number of layers may or may not be consistent between different islands. The positioning of the islands may or may not be symmetric, and the locations of islands can be selected as desired for the formation of a particular product. Laser cutting of a silicon structure on a substrate is described further in copending provisional patent application Ser. No. 60/902,006 to Hieslmair et al., filed on Feb. 16, 2007, entitled “Photovoltaic Cell Structures, Solar Panels and Corresponding Processes,” incorporated herein by reference. The cutting can be performed on a structure as deposited onto a transparent substrate or after transfer to a transparent substrate.

In general, the structures can be processed further using a range of desired approaches. Suitable processing approaches include, for example, conventional approaches adapted for the processing of large surface area structures. For example, the structures can be processed with deposition processes, removal processes and modification processes. Suitable deposition process include, for example, chemical vapor deposition (CVD), physical vapor deposition (PVD), spray coating, brush coating, dip coating, knife coating, extrusion coating, ink jet printing, known or new variations thereof, combinations thereof or the like. Suitable removal processes include, for example, chemical etching, dry etching or radiation-based etching, mechanical polishing, chemical mechanical polishing, known or new variations thereof, combinations thereof or the like. Modification techniques can be used to modify the properties and/or composition of the materials along the surface of the structure. Suitable modification techniques include, for example, heating the structure in an inert, oxidative or reductive environment, contacting the structure with a reactive chemical, directing radiation at the sample, combinations thereof or the like. Deposition, material removal, and/or modification can be preformed in combination with masking or lithographic techniques.

### Formation of Photovoltaic Panels

A photovoltaic panel generally has a plurality of photovoltaic cells assembled onto an appropriate substructure and electrically connected. For example, semiconductor islands can be formed directly onto a protective transparent sheet. Alternatively, the semiconductor structures can be formed for individual cells and anchored onto a protective sheet after separate formation. If large sheets of materials are formed, these can be cut into individual cells with high precision to form selected individual cell elements. The semiconductor islands can be formed with desired structures, dopants and the like with the processing taking place prior to or following placement onto the transparent front surface. The individual cells are electrically interconnected in series, in parallel or combinations thereof. Suitable overlayers, underlayers, encapsulants and the like can be used to complete the panel. For embodiments in which the semiconductor sheet is transferred for formation into a device, the release layer is removed or fractured at a selected stage during the processing of the device. However, if the semiconductor is directly deposited onto a transparent substrate, no transfer of the semiconductor is used to form the photovoltaic structure, and generally no release layer would be formed.

In general, a solar panel is constructed such that light can enter the panel and strike the semiconductor material. The charges generated from absorption of the light are harvested using opposing current collectors. The surfaces of the panel generally are appropriately sealed to protect the materials from environmental assaults. Appropriate wiring can provide electrical connections to the cells of the panel. To increase the electrical conductivity of the semiconductor material, the silicon can be doped through the bulk of the semiconductor material. In particular, the silicon/germanium-based semiconductor can be doped with an n-type dopant, such as phosphorous, or a p-type dopant at a concentration, for example, from 1×10¹⁴ to about 1×10¹⁸ atoms/cm³.

For some embodiments, it is desirable to use layers of silicon/germanium semiconductors that are thin to save material cost but not too thin since semiconductor layers that are too thin may not absorb a desired amount of light. Thus, in some embodiments, the silicon/germanium-based semiconductor can have an average thickness from about 2 micron to about 100 microns, in some embodiments, from about 3 microns to about 80 microns, in further embodiments, from about 4 microns to about 70 microns and in additional embodiments from about 5 microns to about 60 microns. A person of ordinary skill in the art will recognize that additional ranges of the average thickness within the explicit ranges above are contemplated and are within the present disclosure.

In general, the assembly of solar panels from individual solar cells is described further in U.S. Pat. No. 6,818,819 to Morizane et al., entitled “Solar Cell Module,” U.S. Pat. No. 6,307,145 to Kataoka et al., entitled “Solar Cell Module,” U.S. Pat. No. 6,362,021 and U.S. Pat. No. 6,420,643 both to Ford et al., entitled “Silicon Thin-Film, Integrated Solar Cell, Module, and Methods of Manufacturing the Same,” all four of which are incorporated herein by reference. The teachings in these patents can be adapted for the construction off solar cell panels using the thin semiconducting materials described herein.

In general, to form a photovoltaic module from a thin sheet of silicon/germanium-based semiconductor, a large layer of film can be formed that can be used to form the entire module. The silicon/germanium-based semiconductor can be deposited directly onto a transparent substrate, such as a silica glass layer or the like. An additional passivation layer may or may not be deposited between the elemental silicon layer and the transparent substrate. The passivation layer can comprise, for example, silicon oxide (SiO₂) or silicon rich oxide (SiOₓ, x<2). The passivation layers generally can have a thickness generally from about 10 nanometers (nm) to 200 nm and in further embodiments from 30 nm to 180 nm and in further embodiments from 50 nm to 150 nm. Front passivation layer can further function as an antireflective coating. A person of ordinary skill in the art will recognize that additional ranges of thicknesses within the explicit ranges above are contemplated and are within the present disclosure. The surface of the transparent substrate can be textured prior to the deposition process. Appropriate degrees of texturing are described above. In general, the texturing is transferred through the passivation layer and through all or a portion of the semiconductor layer. A rear surface passivation layer can also be formed over the semiconductor sheet.

In additional or alternative embodiments, the thin sheet of silicon/germanium-based semiconductor can be transferred using a release layer. Some processing can be performed onto the silicon foil prior to releasing the layer from the release layer. In some embodiments, a passivation layer and/or texturing is placed on the top surface after deposition and processing. The passivation layer can be deposited using light reactive deposition, CVD, PVD or the like. Texture can be applied using sputter etching or the like. Once any texturing and passivation layer are placed on the semiconductor surface, the surface can be attached to a transparent substrate, for example using an adhesive or the like. Then, the release layer can be severed to release the semiconductor layer. The back surface of the semiconductor can then be processed into the photovoltaic cells.

In these various embodiments, a semiconductor sheet is anchored to a transparent substrate with or without transferring the semiconductor with a release layer. It can be desirable to form an entire module from a single large sheet to facilitate uniformity can performance criteria for the module. The individual cells can be cut from a large sheet to selected sizes.

The cells can be cut from the sheet once the desired division is schematically mapped. The cells can be cut using a diamond edge blade or other mechanical methods. However, available laser cutting techniques provide for particular convenience especially with the real time determination of cell placement. Suitable laser cutting systems are available from Oxford Lasers, Inc., Shirley, Mass., USA, and IPG Photonics Corp., Oxford, Mass., USA (Ytterbium lasers operating at 1070 nm) as well as other commercial sources. The cells are generally cut with the silicon sheet adhered to the transparent substrate. The laser cutting approach may cut into the transparent substrate slightly without damaging cell performance as long as the transparent substrate maintains its mechanical integrity. In general, the laser cutting of the cells can be performed before, after or between steps relating to doping of the contacts.

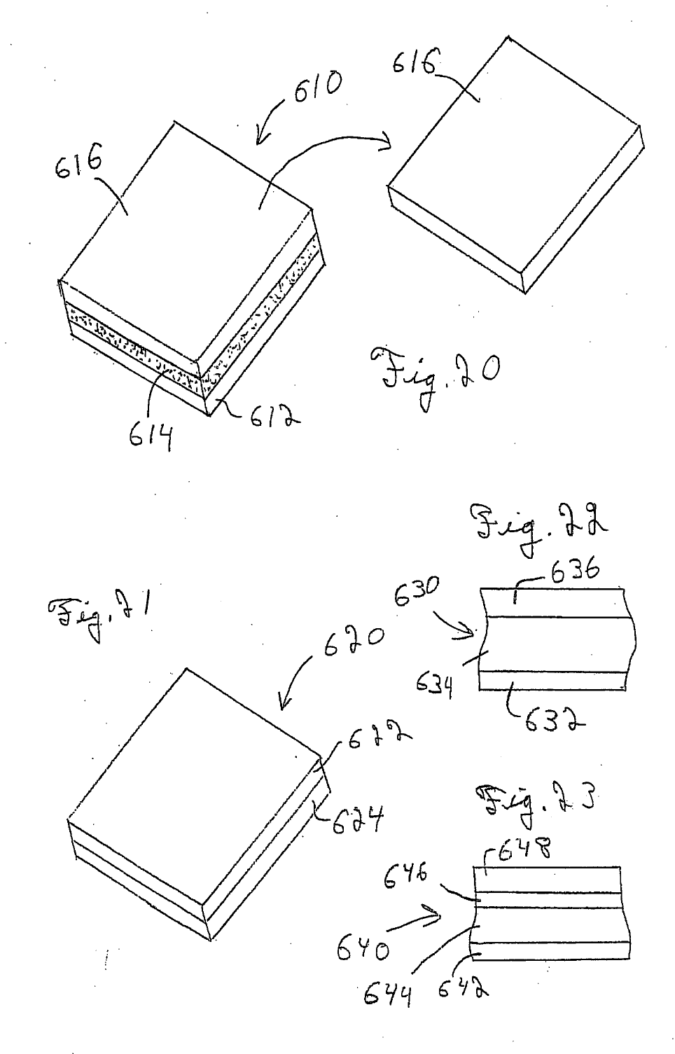

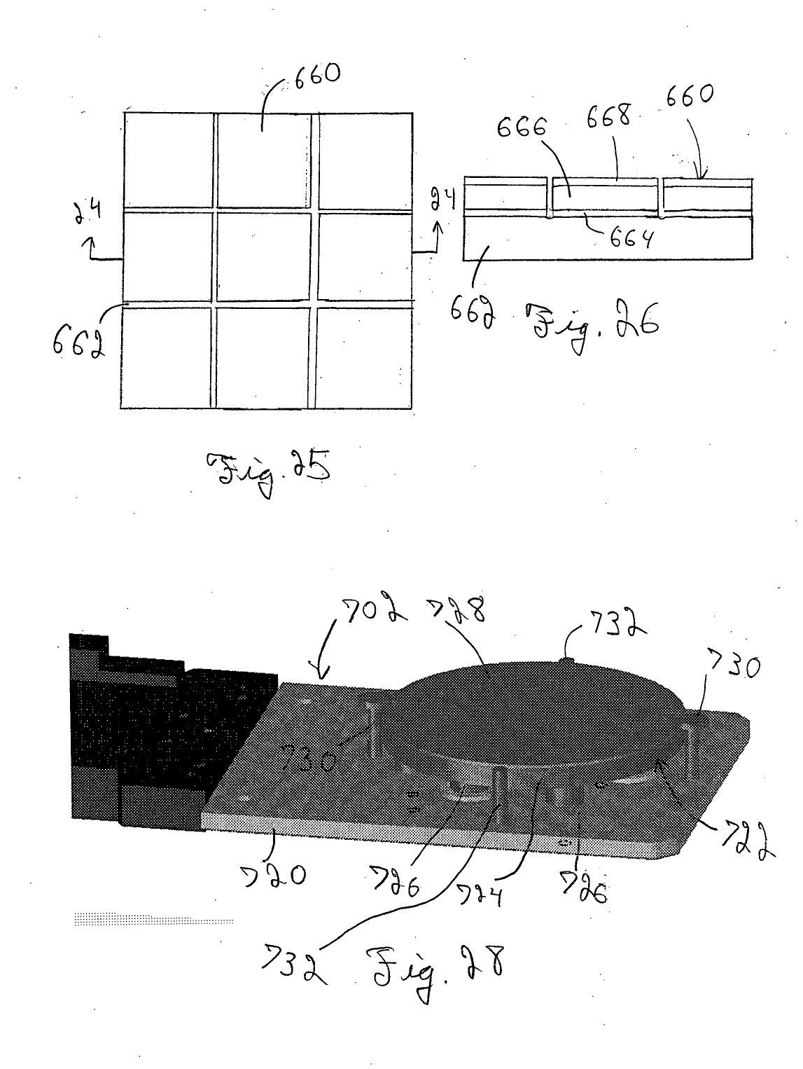

With the front surface bound to the transparent substrate, the back surface of the semiconductor is exposed for further processing. The structure is shown schematically in FIGS. 23 and 24. As shown, nine photovoltaic cells 660 are located on a transparent substrate 662. Referring to FIG. 24, photovoltaic cells 660 comprise a front passivation layer 664, a semiconductor layer 666 and a back passivation layer 668. While shown with nine photovoltaic cells, a module can have different numbers of photovoltaic cells, such as 1 photovoltaic cell, 10 photovoltaic cells, 25 photovoltaic cells, 50 photovoltaic cells, 100 photovoltaic cells, 500 photovoltaic cells, 1000 photovoltaic cells, or more. A person of ordinary skill in the art will recognize that all additional values for the number of photovoltaic cells in a module between these explicit numbers are contemplated and are explicitly within the present disclosure.

In particular approaches to solar cell design, electrical contacts can be designed to have different placements for electrical contacts. The electrical contacts comprise n-doped regions, p-doped regions and appropriate current collectors. For the processing of thin silicon foils described herein, it can be convenient to apply the contacts to the back surface to facilitate handling of the foils. Efficient back surface processing approaches for the formation of photovoltaic cells is described further in copending U.S. Patent application Ser. No. 60/902,006 to Hieslmair et al., filed on Feb. 16, 2007, entitled “Photovoltaic Cell Structures, Solar Panels and Corresponding Processes,” incorporated herein by reference.

### Display Circuits and Other Integrated Circuits Formed from Semiconductor Foils

Thin semiconductor sheets can be a versatile substrate for the formation of circuits for displays as well as other integrated circuit structures. The silicon/germanium semiconductor foils can be further processed with photolithographic techniques and optionally along with other patterning approaches such as printing type technologies. In particular, a sheet of transistor elements, e.g., thin film transistor (TFT) elements, can be formed that can used for the formation of reduced thickness display devices.

In general, thin silicon/germanium-based semiconductor sheets can be deposited onto a permanent substrate or over a release layer on a temporary substrate. The sheet can be patterned to form transistor or other circuit structures. In some embodiments, the silicon/germanium semiconductors can be thinner, such as having a submicron average thickness. The formation of thin film transistors using photolithographic techniques from a thin semiconductor film is described further in U.S. Pat. No. 6,787,806 to Yamazaki et al., entitled “Semiconductor Thin Film and Method of Manufacturing the Same and Semiconductor Device and Method of Manufacturing the Same,” and U.S. Pat. No. 7,115,902 to Yamazaki, entitled “Electro-Optical Device and Method for Manufacturing the Same,” both of which are incorporated herein by reference.

With respect to patterning, dopant can be introduced to thin surface areas along the sheet. These domains can be formed using a printed dopant with heat/oven based, a laser-based or similar dopant drive-in. In embodiments of particular interest, the dopant is delivered in a dopant carrying ink, which can be dispensed using an industrial inkjet. Inkjet resolution over large areas is presently readily available at 200 to 800 dpi, which is adequate to pattern 100 to 200 pitch lines with single drops to cover the laser scribed holes. Also, inkjet resolution is continuing to improve. Two inks generally can be used, with one ink providing n-type dopants, such as phosphorous and/or arsenic, and the second ink providing p-type dopants, such as boron, aluminum and/or gallium.

In general, any reasonable ink can be used that is capable of delivering the desired dopant atoms to the exposed silicon. For example, phosphorous or boron containing liquids can be deposited. In particular, suitable inks can comprise, for example, trioctyl phosphate, phosphoric acid in ethylene glycol and/or propylene glycol or boric acid in ethylene glycol and/or propylene glycol. In some embodiments, inks loaded with inorganic particles can be deposited to provide the dopants. For example, the inorganic particles can comprise doped silica. Doped silica glasses have been used to deliver dopants for photovoltaic cells using photolithographic processes. The use of inks with doped particles can provide similar performance as the photolithographic approaches with the advantages of ink jet printing.

Doped silica (SiO₂) particles generally can be formed from either flow based or solution based approaches. Methods are available for synthesizing inorganic particles in commercial quantities with high uniformity using light-based pyrolysis/laser pyrolysis in which light from an intense electromagnetic radiation source drives the reaction to form the particles. Laser pyrolysis is useful in the formation of particles that are highly uniform in composition, crystallinity and size. Furthermore, inorganic particles can be effectively formed, for example, using laser pyrolysis that results in particles that have desirable surface properties that lead to high dispersibility and ready incorporation into desired structures, although other sources of particles can be used. Doped silica particles formed by laser pyrolysis have been described further in U.S. Pat. No. 6,849,334B to Horne et al., entitled “Optical Materials and Optical Devices,” incorporated herein by reference.

Particles formed by laser pyrolysis generally have appropriate surface chemistry to be dispersed at moderate concentrations. The stability of particle dispersions can be improved at higher concentrations of particles through surface modification of the particles. In general, the surface properties of the particles influence the dispersion of the particles. The surface properties of the particles generally depend on the synthesis approach as well as the post synthesis processing. Some surface active agents, such as many surfactants, act through non-bonding interactions with the particle surfaces. In some embodiments, desirable properties are obtained through the use of surface modification agents that chemically bond to the particle surface. Suitable surface modification agents include, for example, alkoxysilanes, which chemically bond to metal oxide and metalloid oxide particles through an O—Si bond. In particular, trialkoxysilanes form stable bonds with particle surfaces. The side group of the silane influences the resulting properties of the surface modified particles.

To form the inks from the inorganic particle dispersions, other additives can be included if desired, such as viscosity modifiers, surfactants or the like. Dopant inks for doping semiconductors are described further in copending provisional patent application Ser. No. 60/878,239 to Hielsmair filed on Jan. 3, 2007, entitled “Doped Dispersions and Processes for Doping Semiconductor Substrates,” incorporated herein by reference.

After depositing the dopant inks, an optional drying step can be used to remove solvents and/or other organics. A thin film with a thickness of less than a micron can be left for the dopant drive-in process. During the drive-in step, the deposited dopant element is driven into the silicon to form a doped region in the silicon. The drive-in can be performed with heating in an oven to accelerate solid state diffusion. Thermal drive-in of dopants generally results in a Gaussian profile of dopant in the silicon so that a relatively deep dopant structure generally is obtained to obtain a desired overall doping level.

However, in some embodiments, a laser drive-in is performed, for example, with a UV laser, such as an excimer laser. Excimer laser pulses of 10 to 1000 ns can result in melting of silicon at temperatures exceeding 1400° C. to depths of 20 to 80 nm. Dopants in the overlayer diffuse rapidly into the melted silicon, but generally diffuse very little past the melted silicon. Thus, an approximately step-wise dopant profile can be achieved with dopant concentrations possibly reaching levels greater than solubility. Additionally, the bulk of the silicon layer and lower layers remain at or near ambient room temperature. Thus, a heavily doped contact can be formed with a shallow profile, with thickness from about 20 nm to about 100 nm. In some embodiments with a shallow profile, the dopant profile has at least about 95 atomic percent of the dopant in the semiconductor within about 100 nm of the semiconductor surface. The dopant profile can be measured using Secondary Ion Mass Spectrometry (SIMS) to evaluate the elemental composition along with sputtering or other etching to sample different depths from the surface. Excimer laser fluences of about 0.75 J/cm² for a 20 ns pulse or 1.8 J/cm² for a 200 ns pulse are suitable parameters for shallow molten regions.

Some dopant inks may leave little if any residue after drive-in. Dopant inks using doped silica (SiO₂) generally are cleaned from the surface following dopant drive-in. Residual SiO₂ and some impurities can be removed with an HF etch. The resulting semiconductor sheet has doped domains separated by poorly conducting semiconductor domains.

Additional layers can be built up over the semiconductor sheet. These structures can be formed using conventional semiconductor deposition processes, such as photolithography with photoresist and surface based deposition approaches, such as CVD, PVD and the like. Furthermore, spin-on-glasses based on silicates, siloxanes or silsesquioxanes are commercially available from Filmtronics, Inc. In some embodiments, semiconductor inks can be used to deposit semiconductor precursors that can be processed into silicon/germanium-based semiconductor in pure form or with dopants. Polysilanes can be used to form these functional inks that can be processed through moderate heat treatments to decompose into the semiconducting material. Improved functional inks comprising high molecular weight polysilanes with low degrees of crosslinking are described further in copending U.S. patent application Ser. No. 60/901,786 to Dioumauv et al., filed on Feb. 17, 2007, entitled “Functional Inks and Applications Thereof,” incorporated herein by reference. These functional inks can be deposited using any reasonable printing approaches, such as ink jet printing. Printing approaches can be fast and less expensive approaches in comparison with photolithography and related deposition approaches while printing can achieve moderate resolution using existing technology that is expected to further improve. Also, these functional inks can be used to form semiconductor structures using lower temperature processing than conventional processing approaches. The substrates and release layers can be selected to be compatible with the cure temperatures for the ink.

A display incorporating the thin film transistors can be a small, inexpensive display for e-paper, or a larger display for various uses. Photolithography techniques for the formation of TFTs for display applications are described further in U.S. Pat. No. 6,759,711 to Powell, entitled “Method of Manufacturing a Transistor,” incorporated herein by reference.

### EXAMPLE

In this example, the formation of a relatively dense silicon sheet over a release layer is described.

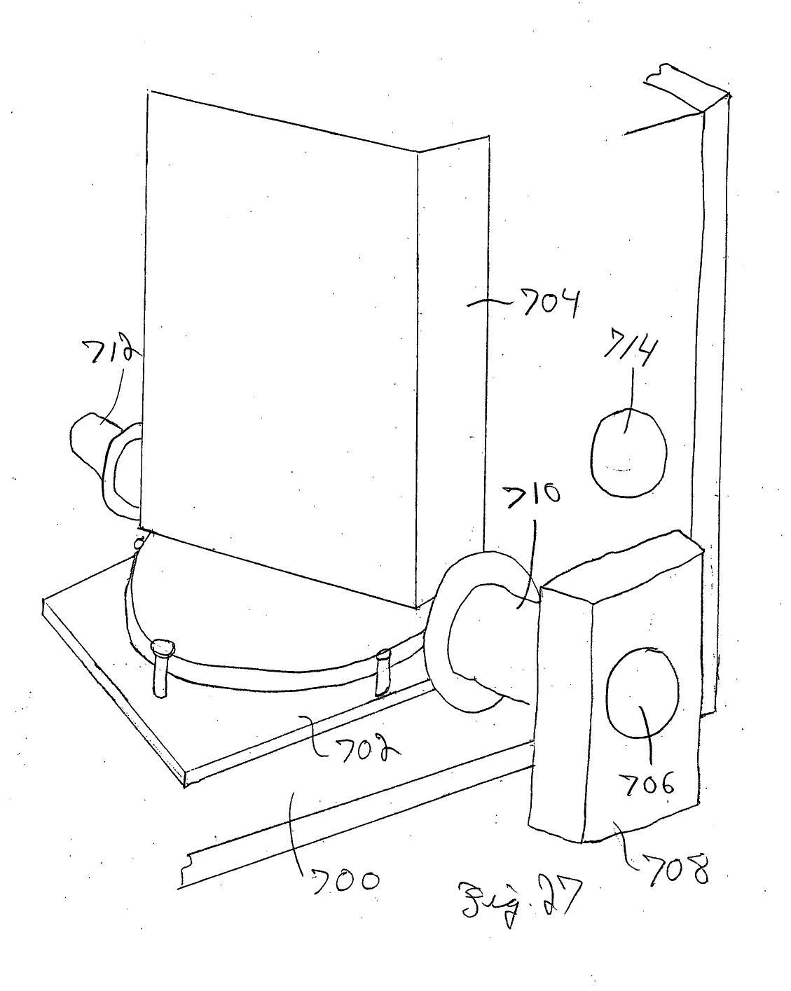

These experiments were performed on an apparatus similar to the apparatus shown in FIGS. 8-10 having a configuration with reactants delivered from the top of the reaction chamber. With respect to the particular apparatus used for the experiments, a cut-away view of reaction chamber 700 showing a stage 702 mounted below the reactant inlet nozzle 704 is shown in FIG. 27. Stage 702 is adjustable such that the distance from the substrate to the center of the light beam can be adjusted between 1 mm to 20 mm. The light beam can enter chamber 700 through opening 706 in mount 708 on light tube 710. An exit light tube 712 receives the beam after transmission through the chamber. Stage 702 connects to an actuator arm that enters chamber 700 through actuator port 714.

A separate view of stage 702 is shown in FIG. 28. Stage 702 comprises a stainless steal support platform 720 with a boron nitride heater 722 mounted on the support platform. The boron nitride heater was obtained from GE Ceramics. Heater 722 has a wafer shaped platform 724 and legs 726. A silicon substrate 728 is held on the top surface of platform 724 with knobs 730 and posts 732. Substrate 728 had a diameter of 4 inches.

During the deposition process, the boron nitride heater kept the substrate at a temperature of about 800° C. Two coating runs were performed. The first coating run deposited a silicon rich nitride release layer and the second run deposited crystalline silicon.

During a run, the stage was moved past the nozzle 1 cycle or 2 passes at a rate specified in Table 1. The reaction conditions for the production of the release layer coating by light reactive deposition are presented in Table 1.

TABLE 1

| | |
|---|---|
| Laser Power (watts) | 1800 |
| Chamber Pressure (Torr) | 100 |
| Substrate Temperature (° C.) | 820 |
| Stage Speed (in/sec) | 30 cm/min |
| Ammonia (sccm) | 400 |
| Argon (sccm) | 500 |
| SiH₄ (sccm) | 50 |
| Deposition Time (min) | |

After the deposition of the release layer, a crystalline silicon layer was deposited according to the conditions in Table 2.

TABLE 2

| | |
|---|---|
| Laser Power (watts) | 1800 |
| Chamber Pressure (torr) | 100 |
| Substrate Temperature (° C.) | 820 |
| Stage Speed (cm/min) | 10 |
| Argon (sccm) | 700 |
| SiH₄ (sccm) | 250 |
| Deposition Time (min) | 5 |

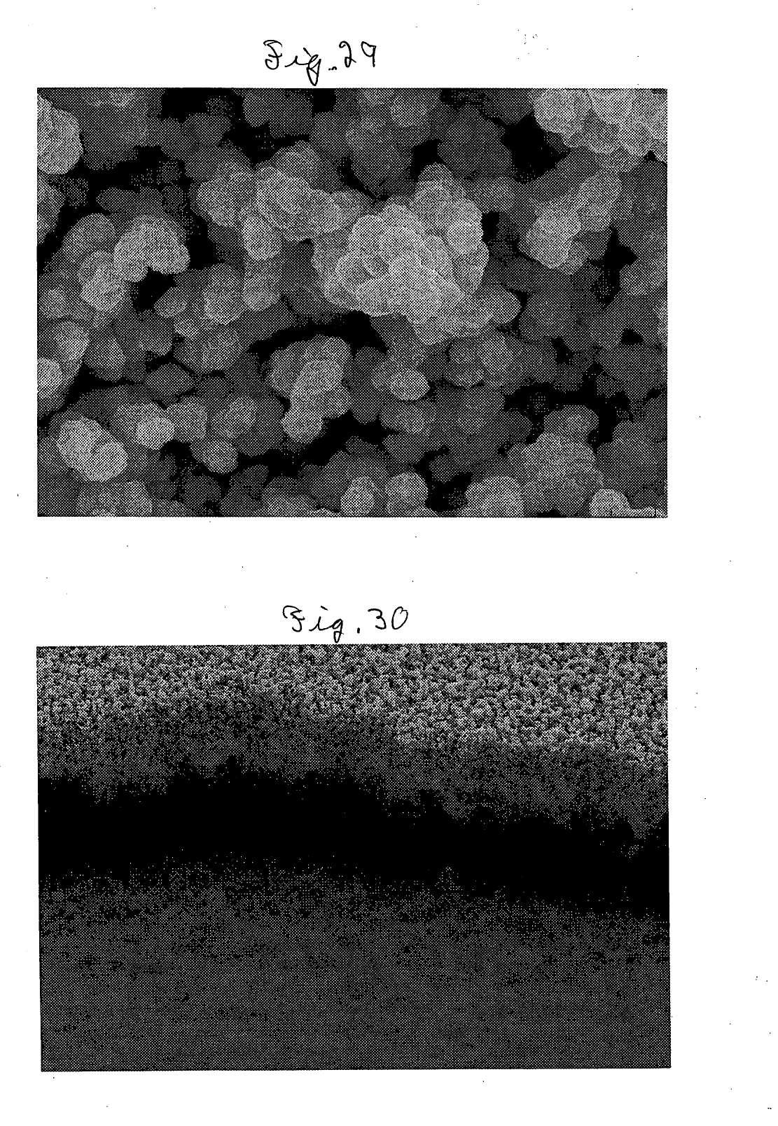

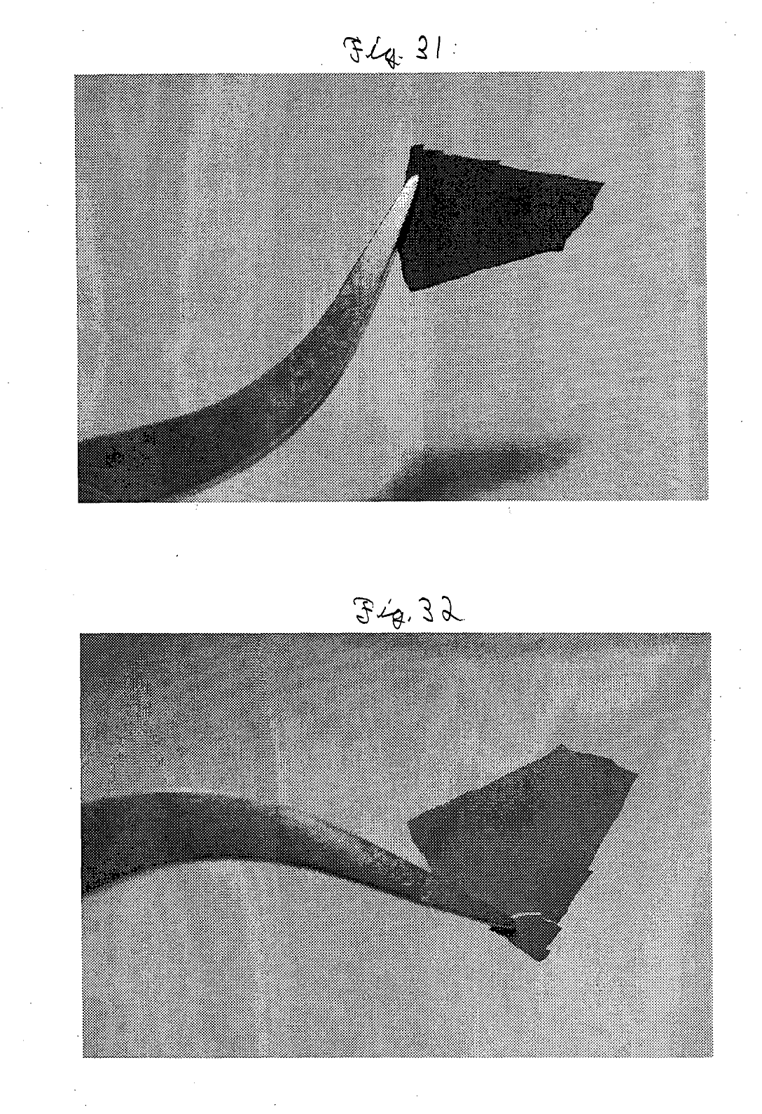

Following completion of a coating run, the substrate appeared to have a uniform gray/black coating across the surface of the wafer. The silicon color was similar to the expected color of elemental silicon. The coating had a thickness of roughly 50 microns with a porosity of about 50%, as measured by scanning electron microscopy (SEM). It was observed that static electricity was sufficient to rupture the release layer in this embodiment. A photomicrograph of the top surface of the resulting silicon foil on the substrate is shown in FIG. 29. FIG. 30 shows the edge where a portion of the silicon foil separated from the release layer and fractured. Remnants of the release layer can be seen on the substrate surface. FIG. 31 shows a fragment of the silicon foil separated from the substrate. FIG. 32 shows the underside of the fragment of FIG. 31 with the lighter color corresponding to the remnants of the release layer.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein.

What is claimed is:

1. A sheet comprising crystalline silicon, germanium, silicon carbide, silicon nitride, doped materials thereof or alloys thereof having an average thickness of no more than about 100 microns and a surface area of at least about 900 square centimeters, wherein the sheet is free or free along one surface while being releasably bound to a substrate along the opposite surface.

2. The sheet of claim 1 wherein the sheet comprises crystalline silicon.

3. The sheet of claim 2 wherein the crystalline silicon is polycrystalline.

4. The sheet of claim 1 wherein the sheet has an average thickness from about 20 nm to about 50 microns.

5. The sheet of claim 1 wherein the sheet has a standard deviation in thickness across the substrate of less than about 5 microns with a 1 centimeter edge exclusion.

6. The sheet of claim 1 wherein the sheet is a free structure.

7. The sheet of claim 1 wherein the sheet is releasably bound to a substrate with adhesive.

8. The sheet of claim 1 wherein the sheet has a minority carrier diffusion length of at least about 30 microns.

9. The sheet of claim 1 wherein the carriers have an electron mobility of at least about 5 cm²/Vs.

10. A method of forming a separable inorganic layer, the method comprising depositing an inorganic material from a reactive flow over an inorganic underlayer on a substrate wherein the underlayer material is soluble in a solvent that does not dissolve the inorganic material.

11. The method of claim 10 wherein the inorganic material comprises crystalline silicon, germanium, silicon carbide, silicon nitride, doped materials thereof or alloys thereof.

12. The method of claim 10 wherein the underlayer material is soluble in an aqueous liquid while the inorganic material is insoluble in the aqueous liquid.

13. The method of claim 10 wherein the underlayer material is soluble in an organic liquid while the inorganic material is insoluble in the organic liquid.

14. A method for forming a separable inorganic layer, the method comprising depositing an inorganic material over an underlayer material having a porosity of at least about 40 percent.

15. The method of claim 14 wherein the inorganic layer comprises silicon, gemanium, silicon carbide, doped materials thereof or alloys thereof.

16. The method of claim 15 wherein the underlayer material comprises silicon oxide, silicon nitride or silicon oxynitride.

17. A structure comprising a plurality of patterned islands of a first inorganic material with an average thickness of no more than about 100 microns, the patterned islands being located on top of a layer of a second inorganic material wherein the second inorganic material comprises a transparent substrate or a release layer.

18. The structure of claim 17 wherein the first inorganic material comprises silicon, germanium, silicon carbide, doped materials thereof or alloys thereof.

19. The structure of claim 17 wherein the second inorganic material comprises silica glass.

20. A method for forming a light receiving structure comprising depositing a semiconductor material onto a textured surface of a transparent substrate.

21. The method of claim 20 wherein the transparent substrate comprises an inorganic glass.

22. The method of claim 20 wherein deposition comprises directing a reactive flow having product compositions formed from the reaction of a reactive flow.

23. The method of claim 22 wherein the reaction is driven by absorption of light.

24. The method of claim 20 wherein the semiconductor material comprises silicon or doped silicon.

25. A method for forming discrete islands of a selected area and an average thickness of no more than about 100 microns, the method comprising cutting a larger sheet secured onto a substrate to form the islands with the selected area, wherein the sheet comprises a crystalline inorganic material.

26. A photovoltaic module comprising discrete islands formed by the method of claim 25 wherein the discrete islands comprise crystalline silicon, crystalline germanium or crystalline alloys thereof and wherein the substrate comprises a transparent inorganic glass.

27. A display comprising a control element and a plurality of light emitting elements with light emission of each element being under the control of the control element, the control element comprising a sheet of silicon/germanium-based semiconductor having an average thickness of no more than about 100 microns wherein the sheet is patterned with transistors operably interfacing with the sheet.
